(19) United States
(12) Patent Application Publication
(10) Pub. No.: US 2025/0107156 A1
(43) Pub. Date: Mar. 27, 2025

(54) DIELECTRIC ISOLATION BETWEEN EPITAXIAL REGIONS AND SUBFIN REGIONS

(71) Applicant: Intel Corporation, Santa Clara, CA (US)

(72) Inventors: Chiao-Ti Huang, Portland, OR (US); Robin Chao, Portland, OR (US); Jaladhi Mehta, Beaverton, OR (US); Tao Chu, Portland, OR (US); Guowei Xu, Portland, OR (US); Ting-Hsiang Hung, Beaverton, OR (US); Feng Zhang, Hillsboro, OR (US); Yang Zhang, Rio Rancho, NM (US); Chia-Ching Lin, Portland, OR (US); Chung-Hsun Lin, Portland, OR (US); Anand Murthy, Portland, OR (US)

(73) Assignee: Intel Corporation, Santa Clara, CA (US)

(21) Appl. No.: 18/471,710

(22) Filed: Sep. 21, 2023

(51) Int. Cl. H01L 29/786; H01L 29/06; H01L 29/417; H01L 29/423; H01L 29/51; H01L 29/66

(52) U.S. Cl. CPC H10D 30/6757; H10D 30/014; H10D 30/6219; H10D 30/6735; H10D 62/121; H10D 64/687

(57) ABSTRACT

Techniques are provided herein to form an integrated circuit having dielectric material formed in cavities beneath source or drain regions. The cavities may be formed within subfin portions of semiconductor devices. In one such example, a FET (field effect transistor) includes a gate structure extending around a fin or any number of nanowires of semiconductor material. The semiconductor material may extend in a first direction between source and drain regions while the gate structure extends over the semiconductor material in a second direction substantially orthogonal to the first direction. A dielectric fill may be formed in a recess beneath the source or drain regions, or a dielectric liner may be formed on sidewalls of the recess, to prevent epitaxial growth of the source or drain regions from the subfins. Removal of the semiconductor subfin from the backside may then be performed without causing damage to the source or drain regions.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. Maintaining a certain level of quality among the various transistor elements can be a challenge due to the number of different fabrication processes to which they may be subjected. Accordingly, there remain a number of non-trivial challenges with respect to forming such semiconductor devices.

### BRIEF DESCRIPTION OF THE DRAWINGS

FIGS. 1A and 1B are different cross-sectional views of an integrated circuit that includes dielectric material in cavities beneath the source and/or drain regions, in accordance with an embodiment of the present disclosure.

FIG. 1C is a plan view of the integrated circuit of FIGS. 1A and 1B, in accordance with an embodiment of the present disclosure.

FIGS. 2A and 2B are cross-sectional views that illustrate one stage in a first example process for forming an integrated circuit configured with dielectric material in cavities beneath the source and/or drain regions, in accordance with an embodiment of the present disclosure.

FIGS. 3A and 3B are cross-sectional views that illustrate another stage in the first example process for forming an integrated circuit configured with dielectric material in cavities beneath the source and/or drain regions, in accordance with an embodiment of the present disclosure.

FIGS. 4A and 4B are cross-sectional views that illustrate another stage in the first example process for forming an integrated circuit configured with dielectric material in cavities beneath the source and/or drain regions, in accordance with an embodiment of the present disclosure.

FIGS. 5A and 5B are cross-sectional views that illustrate another stage in the first example process for forming an integrated circuit configured with dielectric material in cavities beneath the source and/or drain regions, in accordance with an embodiment of the present disclosure.

FIGS. 6A and 6B are cross-sectional views that illustrate another stage in the first example process for forming an integrated circuit configured with dielectric material in cavities beneath the source and/or drain regions, in accordance with an embodiment of the present disclosure.

FIGS. 7A and 7B are cross-sectional views that illustrate another stage in the first example process for forming an integrated circuit configured with dielectric material in cavities beneath the source and/or drain regions, in accordance with an embodiment of the present disclosure.

FIGS. 8A and 8B are cross-sectional views that illustrate another stage in the first example process for forming an integrated circuit configured with dielectric material in cavities beneath the source and/or drain regions, in accordance with an embodiment of the present disclosure.

FIGS. 9A and 9B are cross-sectional views that illustrate another stage in the first example process for forming an integrated circuit configured with dielectric material in cavities beneath the source and/or drain regions, in accordance with an embodiment of the present disclosure.

FIGS. 10A and 10B are cross-sectional views that illustrate another stage in the first example process for forming an integrated circuit configured with dielectric material in cavities beneath the source and/or drain regions, in accordance with an embodiment of the present disclosure.

FIGS. 11A and 11B are cross-sectional views that illustrate another stage in the first example process for forming an integrated circuit configured with dielectric material in cavities beneath the source and/or drain regions, in accordance with an embodiment of the present disclosure.

FIGS. 12A and 12B are cross-sectional views that illustrate another stage in the first example process for forming an integrated circuit configured with dielectric material in cavities beneath the source and/or drain regions, in accordance with an embodiment of the present disclosure.

FIGS. 13A and 13B are cross-sectional views that illustrate one stage in a second example process for forming an integrated circuit configured with dielectric material in cavities beneath the source and/or drain regions, in accordance with an embodiment of the present disclosure.

FIGS. 14A and 14B are cross-sectional views that illustrate another stage in the second example process for forming an integrated circuit configured with dielectric material in cavities beneath the source and/or drain regions, in accordance with an embodiment of the present disclosure.

FIGS. 15A and 15B are cross-sectional views that illustrate another stage in the second example process for forming an integrated circuit configured with dielectric material in cavities beneath the source and/or drain regions, in accordance with an embodiment of the present disclosure.

FIGS. 16A and 16B are cross-sectional views that illustrate another stage in the second example process for forming an integrated circuit configured with dielectric material in cavities beneath the source and/or drain regions, in accordance with an embodiment of the present disclosure.

FIGS. 17A and 17B are cross-sectional views that illustrate another stage in the second example process for forming an integrated circuit configured with dielectric material in cavities beneath the source and/or drain regions, in accordance with an embodiment of the present disclosure.

FIG. 18 illustrates a cross-sectional view of a chip package containing one or more semiconductor dies, in accordance with some embodiments of the present disclosure.

FIG. 19 is a flowchart of a fabrication process for a semiconductor device having dielectric material in cavities beneath the source and/or drain regions, in accordance with an embodiment of the present disclosure.

FIG. 20 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having dielectric material formed in cavities beneath source and/or drain regions. The cavities may be formed within subfin portions of semiconductor devices. The techniques can be used in any number of integrated circuit applications and are particularly useful with respect to logic and memory cells, such as those cells that use finFETs or gate-all-around transistors (e.g., ribbonFETs and nanowire FETs) or forksheet transistors (e.g., nanosheet FETs). In one such example, a FET (field effect transistor) includes a gate structure having a gate electrode on a gate dielectric. The gate structure extends around a fin or any number of nanowires (or nanoribbons or nanosheets, as the case may be) of semiconductor material. The semiconductor material may extend in a first direction between source and drain regions while the gate structure extends over the semiconductor material in a second direction substantially orthogonal to the first direction. Dielectric fill material may be formed beneath the source and/or drain regions to prevent epitaxial growth of the source or drain regions from any part of the subfins. In another example, one or more dielectric layers may be deposited within cavities beneath the source or drain regions such that an airgap exists beneath the source and/or drain regions and surrounded by one or more of the deposited dielectric layers. In either case, removal of the semiconductor subfin from the backside can be subsequently performed without causing damage to the source or drain regions due to the presence of the dielectric material beneath them. In this manner, source and drain regions are decoupled from subfin processing. Numerous variations and embodiments will be apparent in light of this disclosure.

### General Overview

As previously noted above, there remain a number of non-trivial challenges with respect to integrated circuit fabrication. In more detail, as devices become smaller and more densely packed, semiconductor subfins beneath semiconductor regions of the devices can form parasitic junctions between source or drain regions, as at least a portion of the source or drain regions may abut the subfins. In some cases, the source or drain regions may undesirably form on exposed portions of the subfins beneath the devices, via epitaxial growth on the subfins. Furthermore, attempting to remove the subfins from the backside of the structure can damage the underside of the source or drain regions. In operation, these effects can, for instance, reduce the transistor switching speed and degrade the overall performance.

Thus, and in accordance with an embodiment of the present disclosure, techniques are provided herein to isolate or otherwise decouple the source or drain regions from the underlying subfins. The techniques may be used, for instance, to protect the source or drain regions during backside etching processes used to remove the subfins and/or to eliminate undesirable junction formation between the source or drain regions and the subfins. In an example, an etching process (e.g., reactive ion etching (RIE) process) is performed to remove portions of semiconductor fins and form source/drain trenches where the source and drain regions will be. The etching process also etches at least partially into subfin regions beneath the semiconductor fins, forming recesses within the subfin regions that are flanked by a dielectric fill. The dielectric fill may act as shallow trench isolation (STI) between devices. Prior to the formation of the source or drain regions in the source/drain trench, one or more dielectric materials may be formed within the subfin recesses. In one example, the one or more dielectric materials substantially fill the volume of the subfin recesses and the source or drain regions are formed over the filled recesses. In another example, one or more dielectric layers are formed within the recess to cover any exposed portions of the subfin, and the source or drain regions are formed over the one or more dielectric layers. According to some embodiments, the one or more dielectric layers do not fill the volume of the recesses, such that an airgap can exist within a given recess beneath a source or drain region. In any such cases, the deposited dielectric materials within the subfin recesses protect the source or drain regions from various backside processes, such as the backside removal of the semiconductor subfins.

According to an embodiment, an integrated circuit includes a semiconductor device having one or more semiconductor bodies extending in a first direction from a source or drain region and a gate structure extending over the one or more semiconductor bodies in a second direction different from the first direction, a dielectric layer beneath the gate structure, and a dielectric fill beneath the source or drain region. A top surface of the dielectric fill is above a top surface of the dielectric layer.

According to another embodiment, an integrated circuit includes one or more semiconductor bodies extending in a first direction from a source or drain region, a gate structure extending over the one or more semiconductor bodies in a second direction different from the first direction, a dielectric layer beneath the gate structure, and a dielectric liner beneath the source or drain region. The dielectric liner is within a cavity in the dielectric layer such that an air gap exists between a bottom surface of the source or drain region and the dielectric liner within the cavity.

According to another embodiment, a method of forming an integrated circuit includes forming a multilayer fin extending in a first direction over a substrate having first material layers alternating with second material layers, and a subfin beneath the alternating material layers; forming a first dielectric layer adjacent to the subfin; forming a sacrificial gate and spacers on sidewalls of the sacrificial gate, the sacrificial gate extending in a second direction over the multilayer fin, the second direction being different from the first direction; removing an exposed portion of the multilayer fin adjacent to the sacrificial gate and at least a portion of the subfin below the exposed portion of the multilayer fin such that a recess is formed in the subfin; forming a dielectric material within the recess, such that a top surface of the dielectric material is above a top surface of the subfin; forming a source or drain region over the dielectric material and coupled to ends of the second material layers; removing the sacrificial gate and forming a gate structure over the first material layers; removing the subfin from the backside of the integrated circuit; and forming a second dielectric layer in place of the subfin. Another example may use bulk fins (e.g., finFET), instead of multilayer fins (e.g., ribbonFET), wherein the source or drain region is formed over the dielectric material and coupled to the end of the fin.

The techniques can be used with any type of planar or non-planar transistors, including finFETs (sometimes called double-gate transistors, or tri-gate transistors), or nanowire and nanoribbon transistors (sometimes called gate-all-around transistors), or forksheet transistors, to name a few examples. More generally, the techniques described herein may benefit any transistor architecture have a gate dielectric layer that is subjected to relatively high temperature anneals (e.g., 500° C. to 700° C.). The source and drain regions can be, for example, epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of a dielectric region beneath the source or drain regions that is distinct from any surrounding backside dielectric layers (e.g., STI). The dielectric region may include different dielectric materials compared to the backside dielectric layer or there may be a visible seam between the dielectric region and the backside dielectric layer. In some examples, an airgap may be observable within the dielectric region beneath the source or drain regions.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

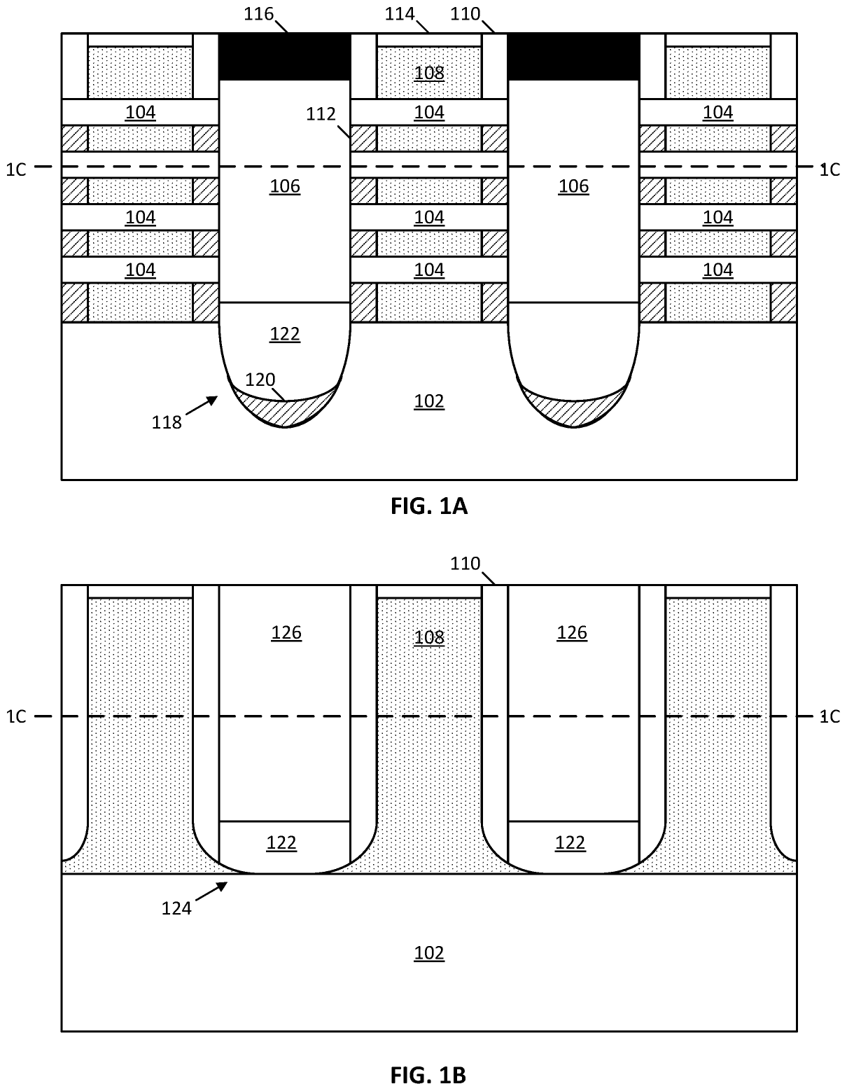

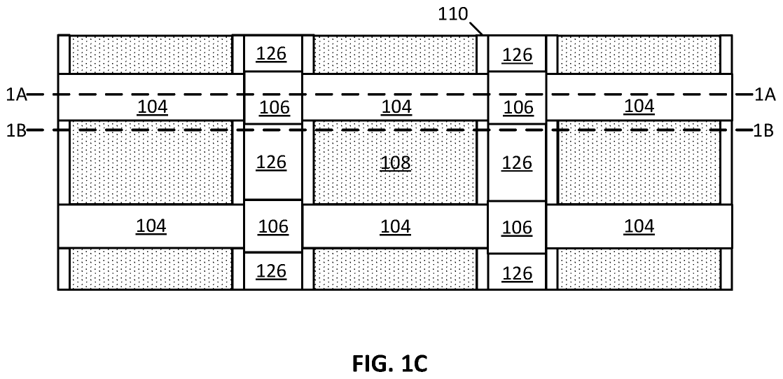

FIG. 1A is a cross-section view taken through various semiconductor devices along a ‘fin’ direction that illustrates the semiconductor bodies extending between source or drain regions of each semiconductor device, in accordance with an embodiment of the present disclosure. FIG. 1B illustrates a cross-section view taken parallel to the cross-section from FIG. 1A and into the page (or out of the page, as the case may be), such that it is away from the semiconductor bodies of the transistors but still crosses the gate structures extending over the semiconductor bodies. FIG. 1C is a top-down cross-section view of the adjacent semiconductor devices taken across the dashed line 1C-1C depicted in both FIG. 1A and FIG. 1B. FIG. 1A illustrates the cross-section taken across the dashed line 1A-1A depicted in FIG. 1C, and FIG. 1B illustrates the cross-section taken across the dashed line 1B-1B depicted in FIG. 1C.

Each of the semiconductor devices may be, for instance, non-planar metal oxide semiconductor (MOS) transistors, such as tri-gate (e.g., finFET) or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions). Other examples may have a forksheet structure having a p-type device and an n-type device separated by a dielectric spine or structure.

The semiconductor material used in each of the semiconductor devices may be formed from a semiconductor substrate. The one or more semiconductor regions of the devices may include fins that can be, for example, native to the substrate (formed from the substrate itself), such as silicon fins etched from a bulk silicon substrate. Alternatively, the fins can be formed of material deposited onto the substrate. In one such example case, a blanket layer of SiGe can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons and nanosheets during a gate forming process where one type of the alternating layers is selectively etched away so as to liberate the other type of alternating layers within the channel region, so that a gate-all-around process or a forksheet gate process can then be carried out. Again, the alternating layers can be blanket deposited and then etched into fins or deposited into fin-shaped trenches, in some examples.

In some embodiments, the substrate is removed and replaced with one or more backside dielectric layers represented by dielectric base layer 102. Accordingly, dielectric base layer 102 may represent STI regions and any number of backside interconnect layers. According to some embodiments, the dielectric layers of dielectric base layer 102 include any suitable dielectric material, such as silicon dioxide.

Each semiconductor device includes one or more semiconductor regions (also called channel regions), such as one or more nanoribbons 104 extending between epitaxial source or drain regions 106 in the first direction. The term nanoribbon may also encompass other similar shapes such as nanowires or nanosheets. A gate structure 108 extends over the one or more semiconductor regions (e.g., nanoribbons 104) of a given semiconductor device in a second direction (e.g., into and out of the page) to form the transistor gate.

Any of source or drain regions 106 may act as either a source region or a drain region, depending on the application and dopant profile. Any semiconductor materials suitable for source and drain regions can be used (e.g., group IV and group III-V semiconductor materials) for any of the illustrated source or drains regions 106. In any such cases, the composition and doping of source or drain regions 106 may be the same or different, depending on the polarity of the transistors. For example, any semiconductor devices that are p-channel transistors have a high concentration of p-type dopants in the associated source or drain regions 106, and any semiconductor devices that are n-channel transistors have a high concentration of n-type dopants in the associated source or drain regions 106. Example p-type dopants include boron and example n-type dopants include phosphorous. Any number of source and drain configurations and materials can be used. In some examples, n-type source or drain regions include silicon doped with phosphorous and p-type source or drain regions include silicon germanium doped with boron.

Gate structure 108 includes a gate dielectric and a gate electrode. The gate dielectric represents any number of dielectric layers present between nanoribbons 104 and the gate electrode. The gate dielectric may also be present on the surfaces of other structures within the gate trench, such as on a surface of dielectric base layer 102. The gate dielectric may include any suitable gate dielectric material(s). In some embodiments, the gate dielectric includes a layer of native oxide material (e.g., silicon dioxide) on the nanoribbons or other semiconductor regions making up the channel region of the devices, and a layer of high-k dielectric material (e.g., hafnium oxide) on the native oxide.

The gate electrode may represent any number of conductive layers on the gate dielectric, such as any metal, metal alloy, or doped polysilicon layers. In some embodiments, the gate electrode includes one or more workfunction metals around nanoribbons 104. In some embodiments, one of the semiconductor devices is a p-channel device that includes a workfunction metal having titanium around its nanoribbons and another semiconductor device is an n-channel device that includes a workfunction metal having tungsten around its nanoribbons. The gate electrode may also include a fill metal or other conductive material around the workfunction metals to provide the whole gate electrode structure.

According to some embodiments, spacer structures 110 and inner spacers 112 are present along the sidewalls of gate structures 108. Spacer structures 110 and inner spacers 112 may be any suitable dielectric material, such as silicon nitride, and provide separation between a given gate structure 108 and the adjacent source or drain region 106. Inner spacers 112 may separate adjacent nanoribbons 104 from one another along a third direction (e.g., a vertical direction).

According to some embodiments, a dielectric cap layer 114 may be present over the gate electrodes within the gate trenches of the semiconductor devices. A top surface of dielectric cap layer 114 may be substantially co-planar with a top surface of spacer structures 110. Dielectric cap layer 114 may include the same dielectric material as spacer structures 110, in some examples.

According to some embodiments, conductive contacts 116 are provided on source or drain regions 106. Conductive contacts 116 can include any suitable conductive material, such as tungsten, molybdenum, ruthenium, cobalt, or other metals. Conductive contacts 116 may be formed together such that they all include the same conductive material. In some examples, conductive contacts 116 include a silicide layer (e.g., a layer having titanium and silicon) directly on the top surface of source or drain regions 106.

According to some embodiments, dielectric regions 118 are provided beneath source or drain regions 106 that include one or more dielectric materials. In some examples, a bottom portion of dielectric regions 118 includes a bottom dielectric layer 120. According to some embodiments, bottom dielectric layer 120 may be formed during the same process that forms inner spacers 112, and thus bottom dielectric layer 120 may be the same dielectric material as inner spacers 112. According to some embodiments, a remaining volume of dielectric regions 118 is filled or substantially filled with a dielectric fill 122. Dielectric fill 122 may be any suitable dielectric material with a high etch selectivity to the dielectric material of bottom dielectric layer 120 and inner spacers 112. In one example, dielectric fill 122 includes silicon dioxide while bottom dielectric layer 120 and inner spacers 112 include silicon nitride. According to some embodiments, a top surface of dielectric regions 118 (e.g., a top surface of dielectric fill 122) is above a top surface of base dielectric layer 102 and below a bottom surface of the bottom-most nanoribbon 104. Accordingly, source or drain 106 growth is constrained to the region above dielectric region 118 and is prevented from growing from any preexisting subfin portions.

According to some embodiments, the formation of dielectric regions 118 can have an additional benefit of masking gate foot regions 124 that can extend partially into the source/drain trench adjacent to source or drain regions 106. FIG. 1B illustrates how dielectric fill 122 covers gate foot regions 124 that can extend below a bottom of spacer structures 110. This can protect source or drain regions 106 from damage during the gate formation process, as will be discussed in more detail herein. Also illustrated in FIG. 1B are dielectric plugs 126 that fill portions of the source/drain trench between different source or drain regions, according to some embodiments. Dielectric plugs 126 may be any suitable dielectric material, such as silicon dioxide. As shown in FIG. 1C, the cross-section of FIG. 1B is taken parallel to the cross-section of FIG. 1A and closely adjacent in the second direction to source or drain regions 106 of FIG. 1A.

### Fabrication Methodology

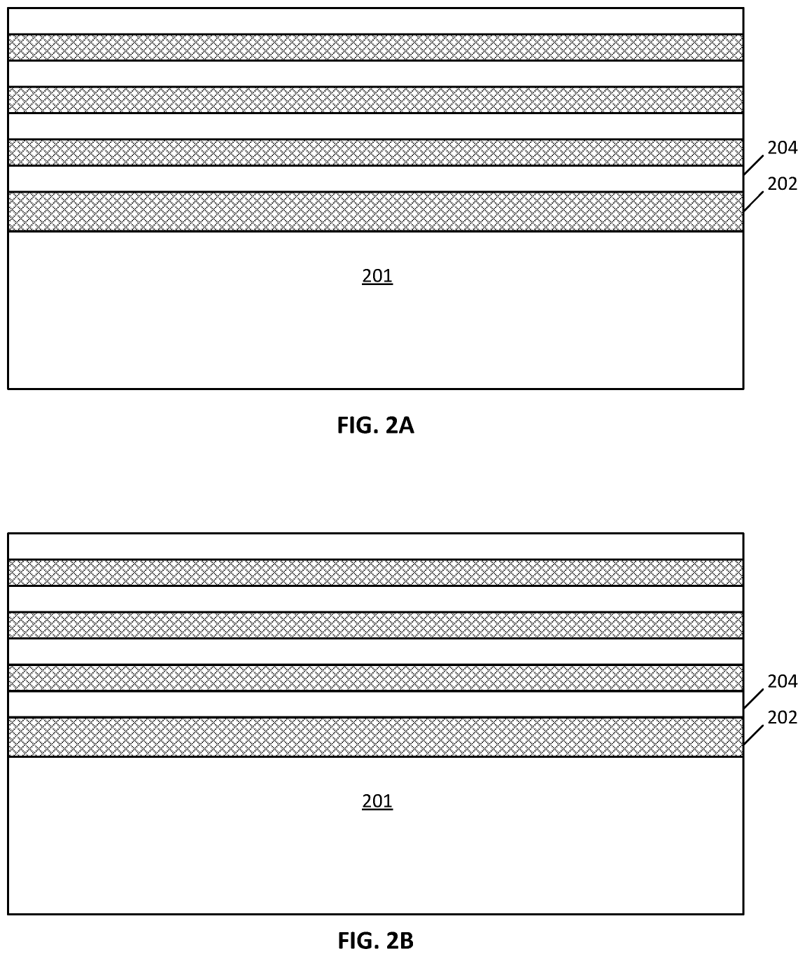

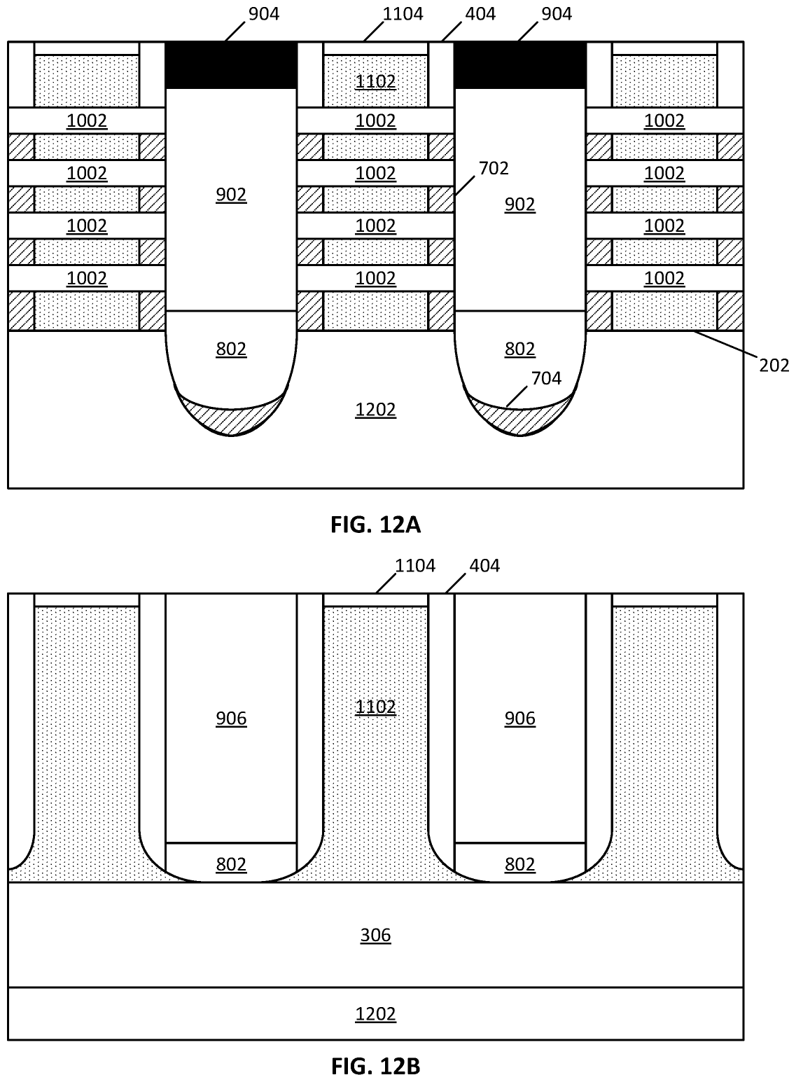

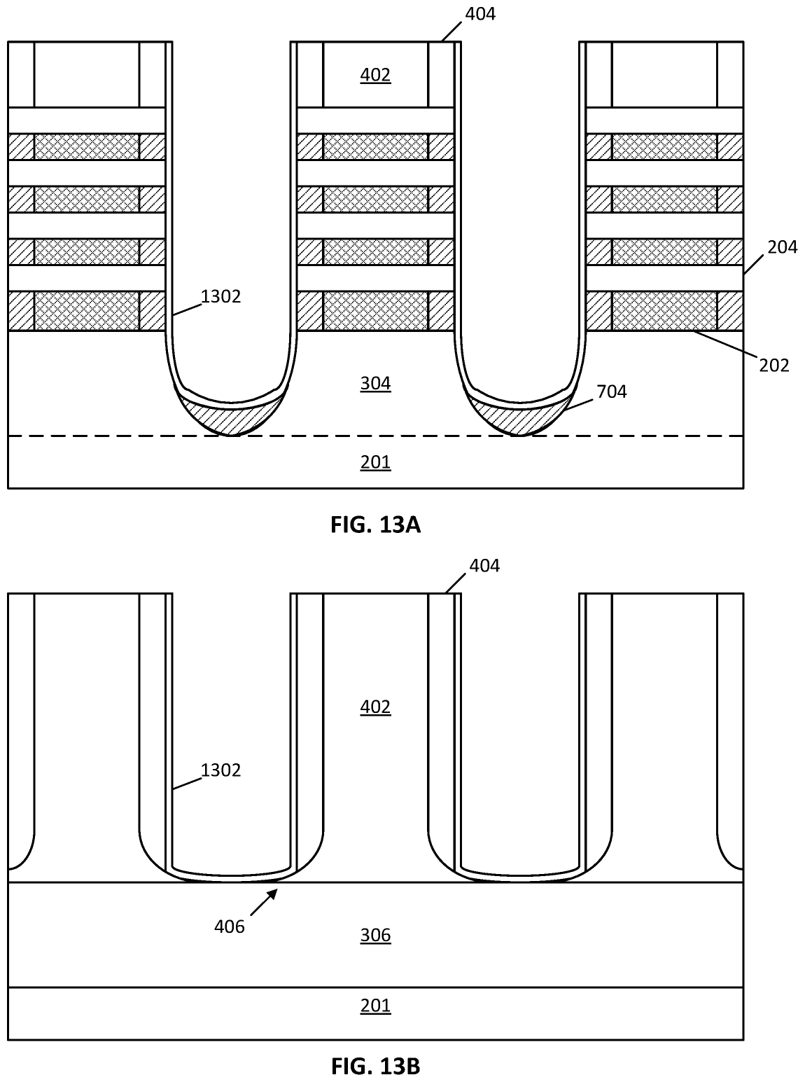

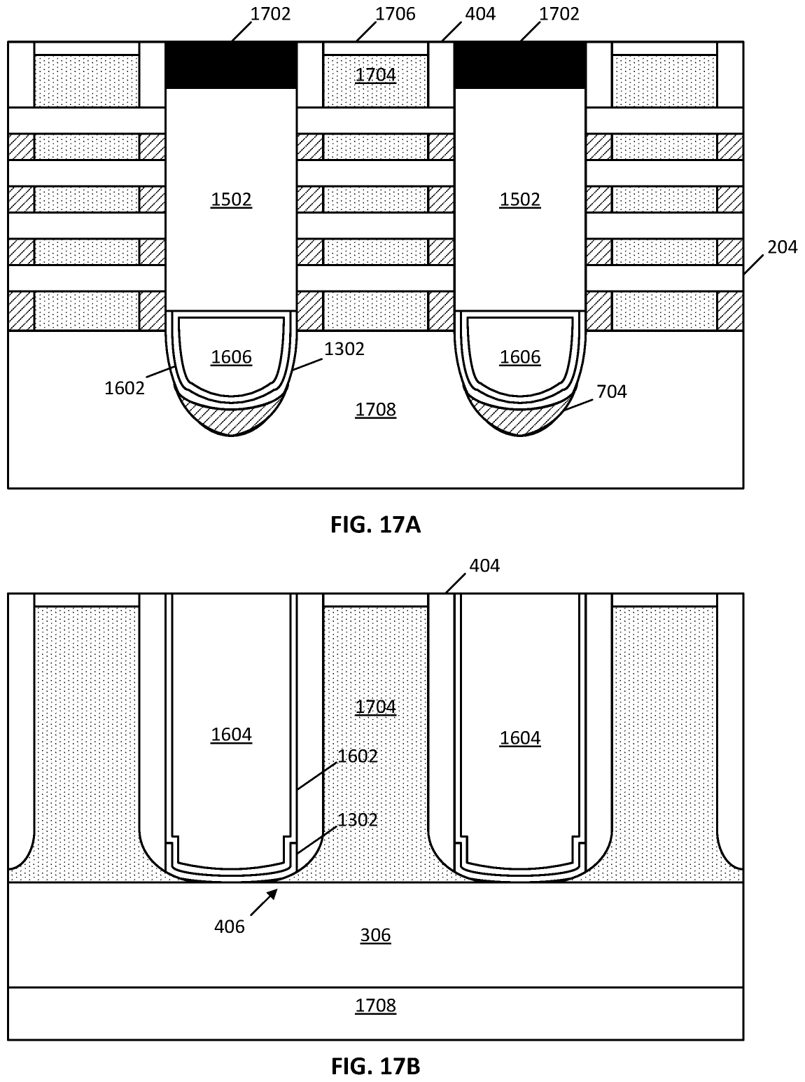

FIGS. 2A-12A and 2B-12B include cross-sectional views that collectively illustrate a first example process for forming an integrated circuit configured with dielectric material in cavities beneath the source or drain regions, in accordance with an embodiment of the present disclosure. FIGS. 13A-17A and 13B-17B include cross-sectional views that collectively illustrate a second example process for forming an integrated circuit configured with dielectric material in cavities beneath the source or drain regions, in accordance with an embodiment of the present disclosure. FIGS. 2A-17A represent a similar cross-sectional view as that of FIG. 1A across a series of semiconductor devices, while FIGS. 2B-17B represent a similar cross-sectional view as that of FIG. 1B parallel to the view in FIGS. 2A-17A and adjacent to the semiconductor devices. Each set of figures sharing the same letter shows an example structure that results from the process flow up to that point in time, so the depicted structure evolves as the process flow continues, culminating in the first example structure shown in FIGS. 12A-12B, which is similar to the structure shown in FIGS. 1A and 1B, and the second example structure in FIGS. 17A and 17B. Such example structures may be part of an overall integrated circuit (e.g., such as a processor or memory chip) that includes, for example, digital logic cells and/or memory cells and analog mixed signal circuitry. Thus, the illustrated integrated circuit structures may be part of a larger integrated circuit that includes other integrated circuitry not depicted. Example materials and process parameters are given, but other materials and process parameters may be used as well, as will be appreciated in light of this disclosure.

FIGS. 2A and 2B each illustrates a cross-sectional view taken through a substrate 201 having a series of material layers formed over a substrate, according to an embodiment of the present disclosure. Alternating material layers may be deposited over substrate 201 including sacrificial layers 202 alternating with semiconductor layers 204. The alternating layers are used to form GAA transistor structures. Any number of alternating sacrificial layers 202 and semiconductor layers 204 may be deposited over substrate 201.

Substrate 201 can be, for example, a bulk substrate including group IV semiconductor material (such as silicon, germanium, or SiGe), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, semiconductor layers 204 have a different material composition than sacrificial layers 202. In some embodiments, semiconductor layers 204 include a semiconductor material suitable for use as a nanoribbon such as silicon (Si), SiGe, germanium, or III-V materials like indium phosphide (InP) or gallium arsenide (GaAs). Sacrificial layers 202 include a material that can be selectively removed relative to semiconductor layers 204. In some examples, for instance, semiconductor layers 204 are silicon and sacrificial layers 202 are SiGe, or vice-versa. In some other examples where SiGe is used in each of semiconductor layers 204 and in sacrificial layers 202, the germanium concentration is different between semiconductor layers 204 and sacrificial layers 202, so as to allow for etch selectivity. For example, semiconductor layers 204 may include a higher germanium content compared to sacrificial layers 202.

While dimensions can vary from one example embodiment to the next, the thickness of each semiconductor layer 204 may be between about 5 nm and about 20 nm, in some examples. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). In some embodiments, a bottom-most sacrificial layer 202 (e.g., formed directly on substrate 201) is thicker than the other sacrificial layers 202. For example, the bottom sacrificial layer 202 may be 25%, 50%, 75%, or 100% thicker compared to the thickness of the remaining sacrificial layers 202. Each of semiconductor layers 204 and sacrificial layers 202 may be deposited using any material deposition technique, such as chemical vapor deposition (CVD), plasma-enhanced chemical vapor deposition (PECVD), physical vapor deposition (PVD), or atomic layer deposition (ALD), or epitaxial growth.

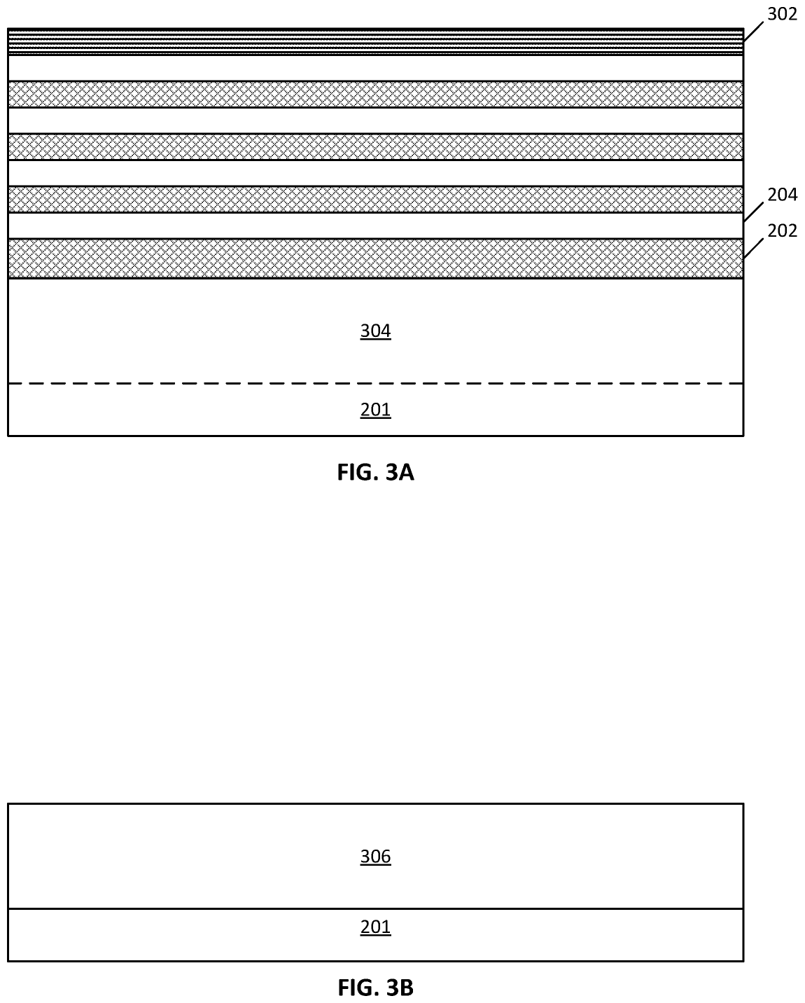

FIGS. 3A and 3B depict the cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. Cap layer 302 extends along the top of each fin in a first direction, as seen in FIG. 3A.

According to some embodiments, an anisotropic etching process through the layer stack continues into at least a portion of substrate 201. Portions of substrate 201 beneath cap layer 302 and the fins are not etched and yield subfin regions 304 as illustrated in FIG. 3A. The etched portions of substrate 201 that are not under the fins may be filled with a dielectric fill 306 that acts as STI between adjacent fins as illustrated in FIG. 3B. Dielectric fill 306 may be any suitable dielectric material such as silicon dioxide. Subfin regions 304 represent remaining portions of substrate 201 flanked by dielectric fill 306, according to some embodiments.

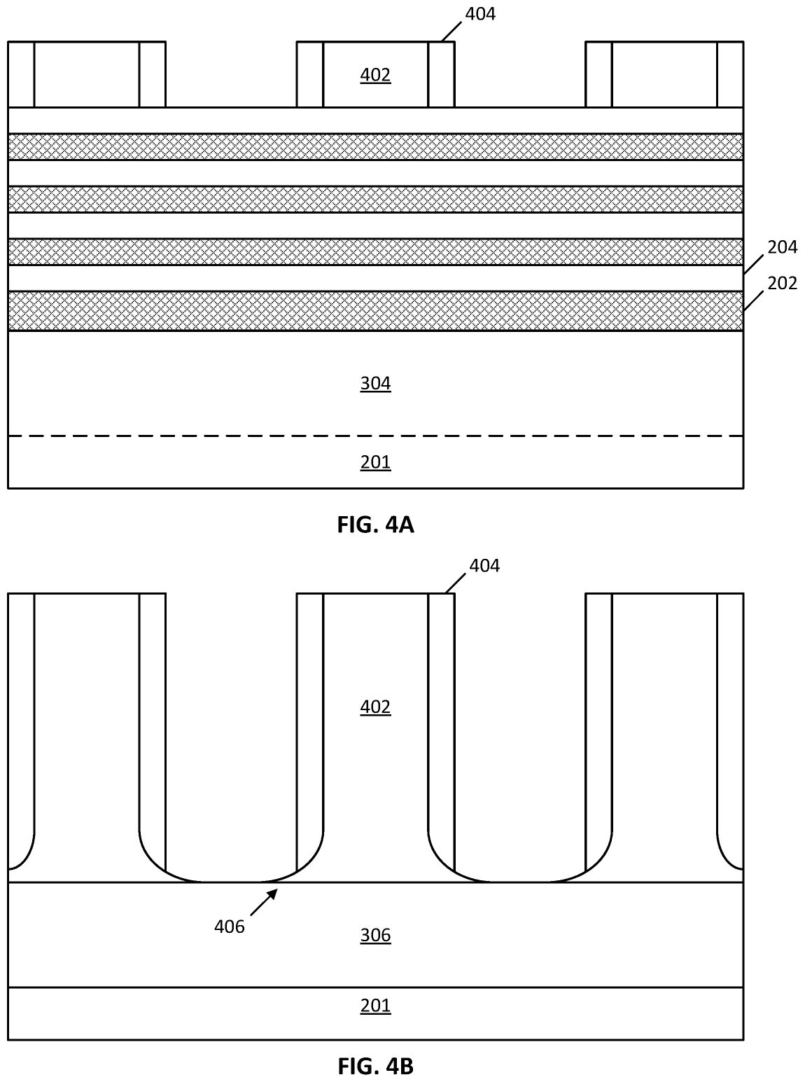

FIGS. 4A and 4B depict cross-section views of the structures shown in FIGS. 3A and 3B following the formation of sacrificial gates 402 and spacer structures 404, according to some embodiments. A gate masking layer may first be patterned in strips that extend orthogonally across each of the fins (e.g., in a second direction) in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. As seen in FIG. 4B, the bottom of sacrificial gate 402 may flare outwards due to the proximity of the semiconductor fin. This fabrication effect creates gate foot regions 406 that extend towards the middle of the source/drain trenches between adjacent gate trenches. Sacrificial gate 402 may be any suitable material that can be selectively removed without damaging the semiconductor material of the fins. In some examples, sacrificial gate 402 includes polysilicon.

According to some embodiments, spacer structures 404 are formed along the sidewalls of sacrificial gates 402. Spacer structures 404 may be conformally deposited (e.g., CVD or ALD)_and then etched back or otherwise removed (e.g., via anisotropic or directional etch) from horizontal surfaces, such that spacer structures 404 remain mostly only on sidewalls of any exposed structures. The width of spacer structures 404 (along the first direction) may vary from one example to the next, but in some cases is in the range of 3 nm to 20 nm. According to some embodiments, spacer structures 404 may be any suitable dielectric material, such as silicon nitride, silicon carbon nitride, or silicon oxycarbonitride. In one such embodiment, spacer structures 404 comprise a nitride and dielectric fill 306 comprises an oxide, so as to provide a degree of etch selectivity during final gate processing. Other etch selective dielectric schemes (e.g., oxide/carbide, carbide/nitride) can be used as well for spacer structures 404 and dielectric fill 306. In other embodiments, spacer structures 404 and dielectric fill 306 are compositionally the same or otherwise similar, where etch selectivity is not employed.

According to some embodiments, spacer structures 404 extend in a third direction (e.g., vertical direction) onto a top surface of gate foot regions 406, but do not cover the entirety of gate foot regions 406. The dielectric material of spacer structures 404 may be removed from the more horizontal portions of gate foot regions 406 during the etch-back process. Accordingly, portions of sacrificial gate 402 may be exposed at the bottom of the source/drain trench.

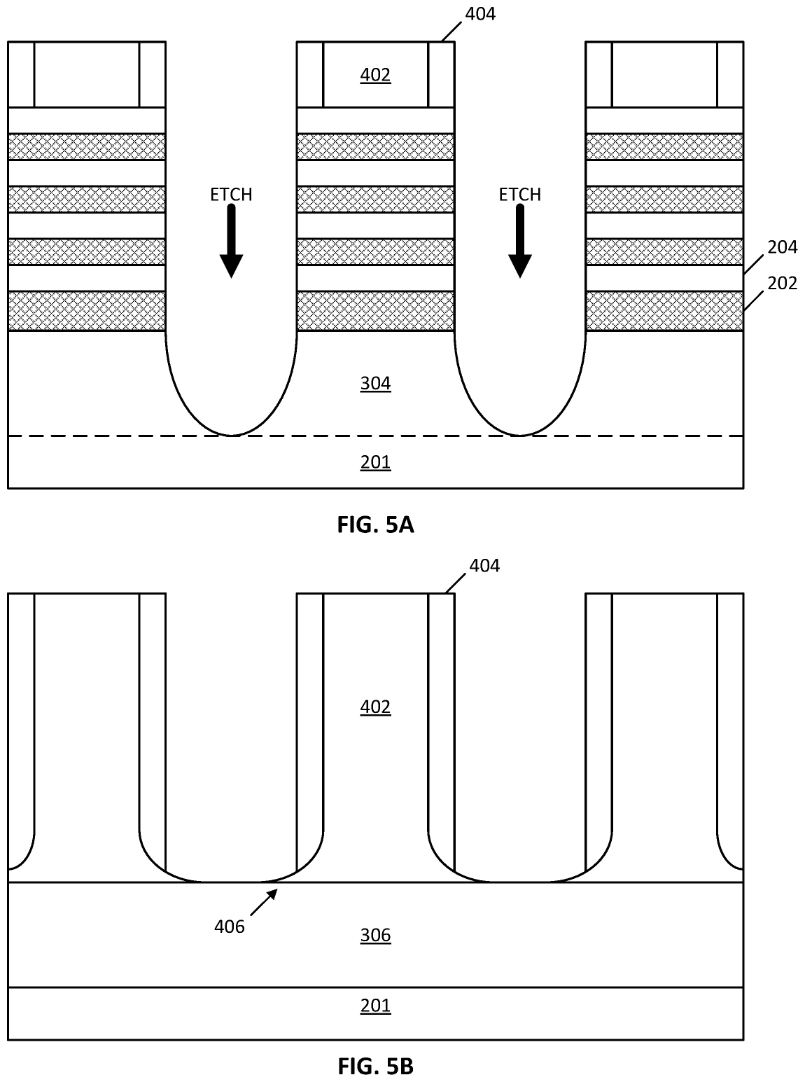

FIGS. 5A and 5B depict cross-section views of the structures shown in FIGS. 4A and 4B following the removal of exposed portions of the fins not protected by sacrificial gates 402 and spacer structures 404, according to some embodiments. The exposed fin portions may be removed using any anisotropic etching process, such as reactive ion etching (RIE) or other directional etch process. The exposed fin portions are removed from within the source/drain trenches that alternate with gate trenches (currently filled with sacrificial gates 402) along the first direction, according to some embodiments. In some embodiments, at least a portion of subfin regions 304 is also removed during the etching process, thus forming subfin recesses. The subfin recesses may have a tapered profile due to the high aspect ratio of the trenches. Some exposed portions of gate foot regions 406 may also be removed during the etching process used to remove the portions of the semiconductor fins.

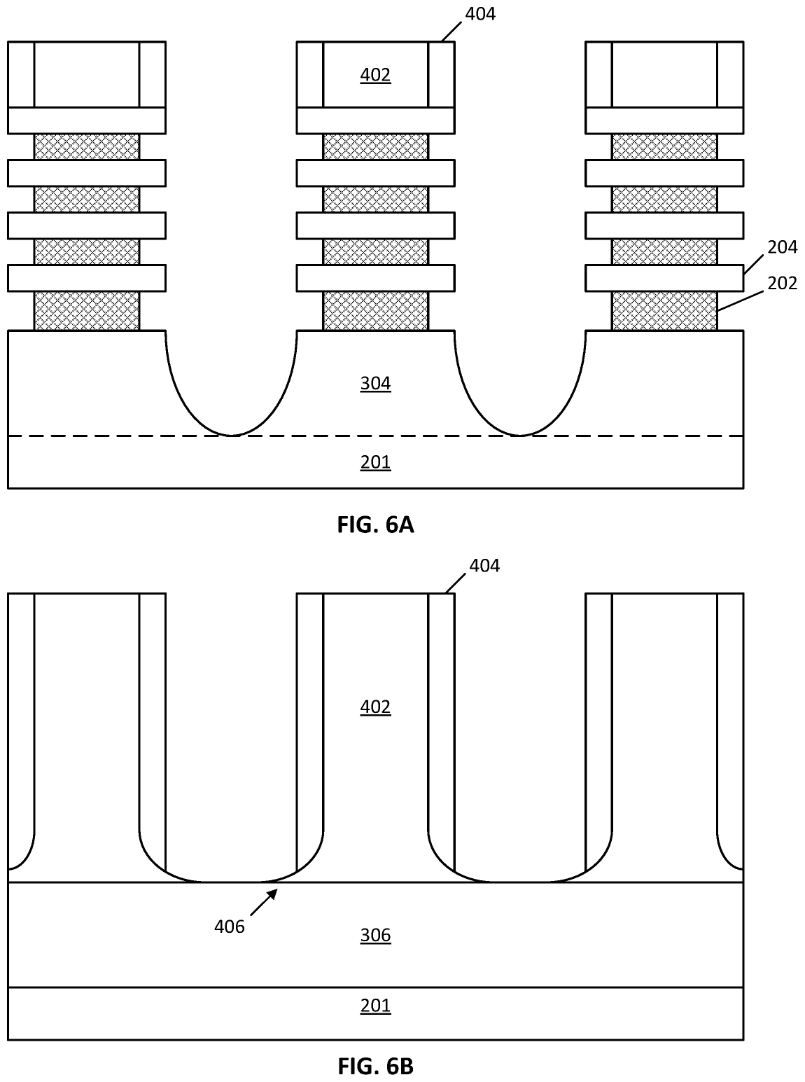

FIGS. 6A and 6B depict cross-section views of the structures shown in FIGS. 5A and 5B following the removal of portions of sacrificial layers 202, according to an embodiment of the present disclosure. An isotropic etching process may be used to selectively recess the exposed ends of each sacrificial layer 202 (e.g., while etching comparatively little of semiconductor layers 204).

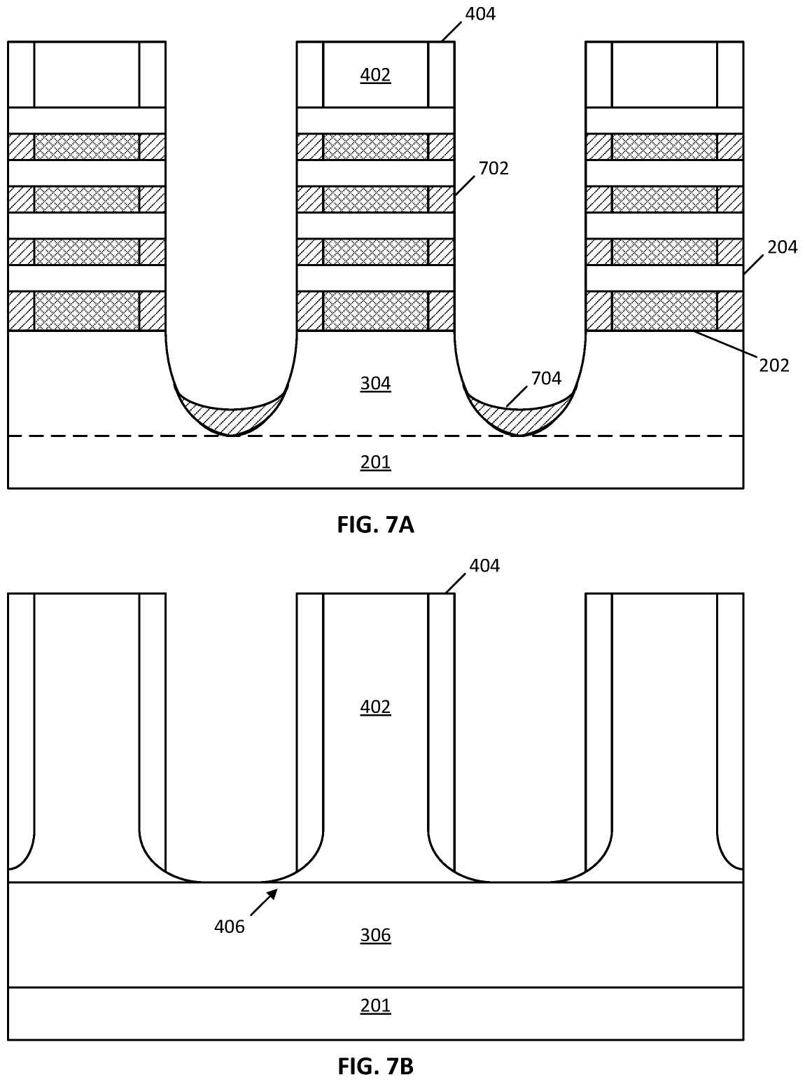

FIGS. 7A and 7B depict cross-section views of the structures shown in FIGS. 6A and 6B following the formation of internal spacers 702, according to an embodiment of the present disclosure. Internal spacers 702 may have a material composition that is similar to or the exact same as spacer structures 404. Accordingly, internal spacers 702 may be any suitable dielectric material that exhibits high etch selectively to semiconductor materials such as silicon and/or silicon germanium. Internal spacers 702 may be, for example, conformally deposited over the sides of the fin structure using a conformal deposition process like CVD or ALD and then etched back using an isotropic etching process to expose the ends of semiconductor layers 204. According to some embodiments, a portion of the dielectric material at the bottom of the subfin recesses remains after the etch-back process and forms bottom dielectric layer 704. Thus, bottom dielectric layer 704 may be the same dielectric material as internal spacers 702. According to some embodiments, internal spacers 702 have a similar width (e.g., along the first direction) to spacer structures 404. Note that internal spacers 702 may be formed around the ends of semiconductor layers 204 and not along other edges of the gate trench away from semiconductor layers 204 (as shown in FIG. 7B), according to some embodiments.

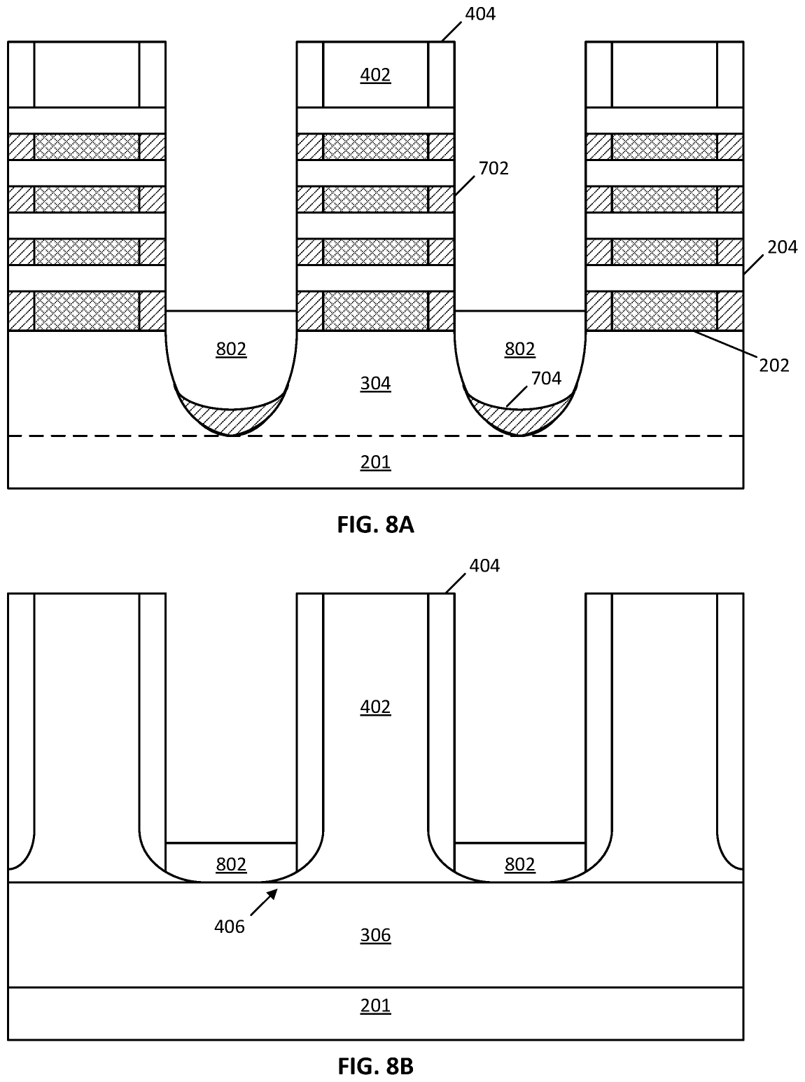

FIGS. 8A and 8B depict cross-section views of the structure shown in FIGS. 7A and 7B, respectively, following the formation of a dielectric fill 802 within at least a remaining volume of the subfin recesses, according to some embodiments. Dielectric fill 802 may be formed within the source/drain trenches and subsequently recessed to a final height that puts a top surface of dielectric fill 802 at least above a top surface of the adjacent subfin regions 304. According to some embodiments, the top surface of dielectric fill 802 is below the bottom surface of the bottom-most semiconductor layer 204 in the fins. As shown in FIG. 8B, dielectric fill 802 also forms within the bottom of the source/drain trench and thus can cover gate foot regions 406. Dielectric fill 802 may be any suitable dielectric material that exhibits good etch selectively with spacer structures 404 and internal spacers 702. In some examples, dielectric fill 802 includes silicon dioxide and spacer structures 404 and internal spacers 702 include silicon nitride.

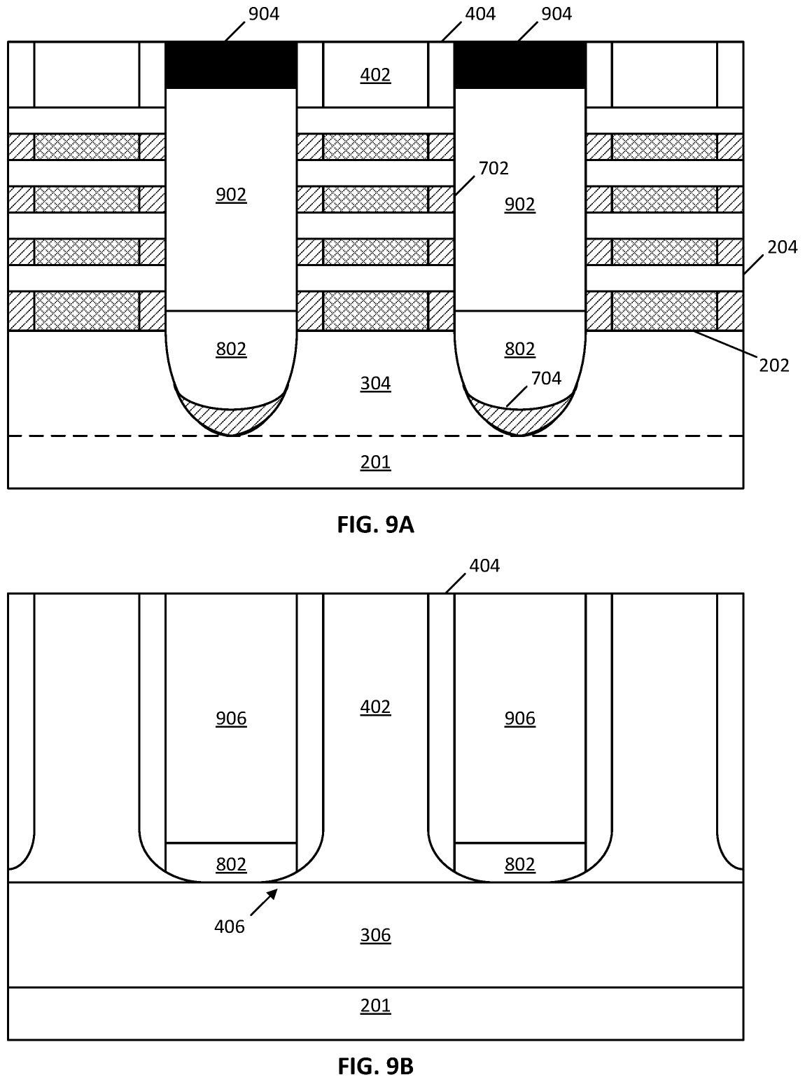

FIGS. 9A and 9B depict cross-section views of the structure shown in FIGS. 8A and 8B, respectively, following the formation of source or drain regions 902 within the source/drain trenches, according to some embodiments. Source or drain regions 902 may be formed in the areas that had been previously occupied by the exposed fins between spacer structures 404. According to some embodiments, source or drain regions 902 are epitaxially grown from the exposed semiconductor material at the ends of semiconductor layers 204. In some example embodiments, source or drain regions 902 are n-channel source or drain regions (e.g., epitaxial silicon with n-type dopants) or p-channel source or drain regions (e.g., epitaxial SiGe with p-type dopants). Contacts 904 may be formed over the top surfaces of source or drain regions 902. Contacts 904 may include any suitable conductive material, such as tungsten, cobalt, molybdenum, or ruthenium, for making electrical contact with the underlying source or drain regions 902. In some embodiments, the regions above source or drain regions 902 is filled with a dielectric that is replaced with contacts 904 after the replacement of sacrificial gates 402 with gate structures. Due to the presence of dielectric fill 802, no part of source or drain regions 902 are grown from subfin regions 304, according to some embodiments.

According to some embodiments, a dielectric fill 906 is provided between adjacent source or drain regions 902 along a given source/drain trench running in the second direction. In some examples, dielectric fill 906 occupies a remaining volume within the source/drain trench around and possibly over portions of source or drain regions 902. Dielectric fill 906 may be any suitable dielectric material, such as silicon dioxide. In some examples, dielectric fill 906 extends up to and planar with a top surface of spacer structures 404 (e.g., following a polishing procedure).

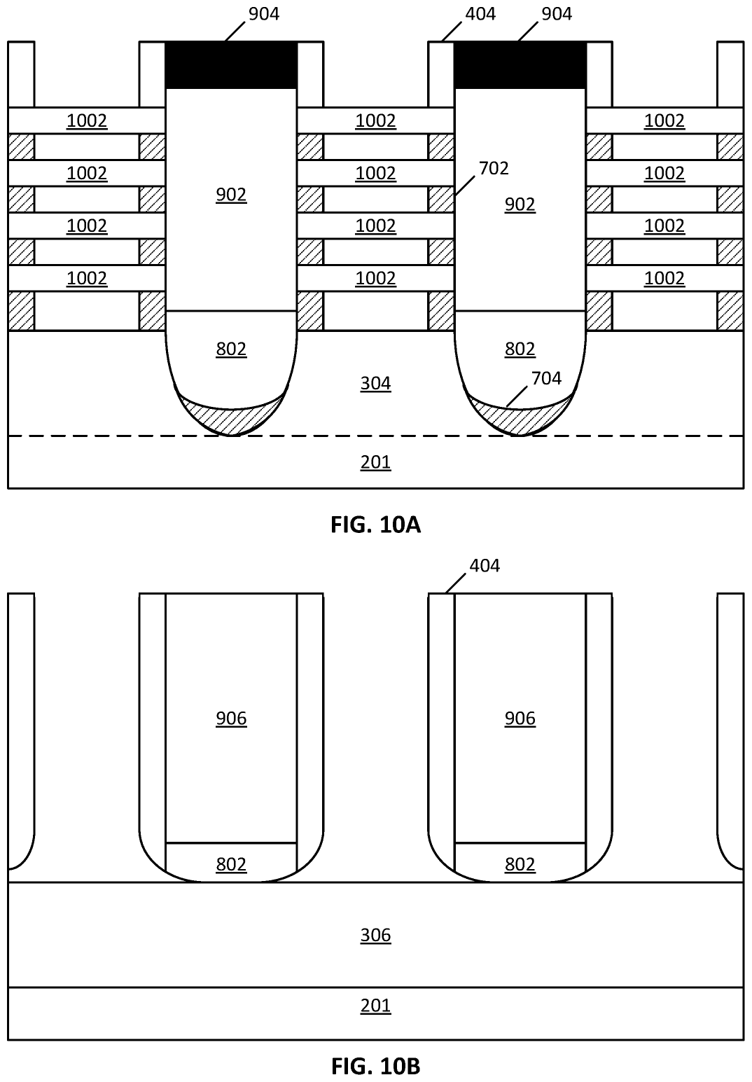

FIGS. 10A and 10B depict cross-section views of the structure shown in FIGS. 9A and 9B, respectively, following the removal of sacrificial gates 402 and sacrificial layers 202, according to some embodiments. In examples where gate masking layers are still present, they may be removed at this time. Once sacrificial gates 402 are removed, the fins extending between spacer structures 404 are exposed.

In the example where the fins include alternating sacrificial layers 202 and semiconductor layers 204, sacrificial layers 202 are selectively removed to leave behind nanoribbons 1002 that extend between corresponding source or drain regions 902. Each vertical set of nanoribbons 1002 represents the semiconductor region (also called channel region) of a different semiconductor device. It should be understood that nanoribbons 1002 may also be nanowires or nanosheets. Sacrificial gates 402 and sacrificial layers 202 may be removed using the same isotropic etching process or different isotropic etching processes.

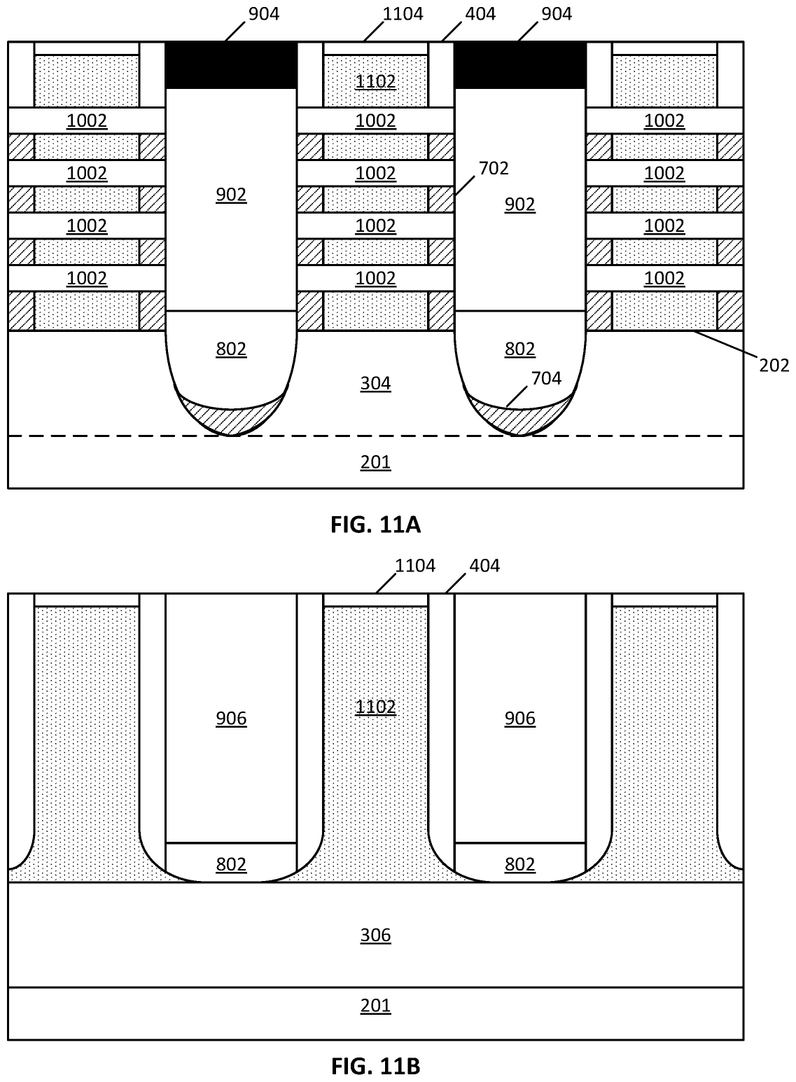

FIGS. 11A and 11B depict cross-section views of the structure shown in FIGS. 10A and 10B, respectively, following the formation of a gate structure 1102 around nanoribbons 1002 within the gate trench, according to some embodiments. As noted above, gate structure 1102 includes a gate dielectric and a gate electrode on the gate dielectric. The gate dielectric may be conformally deposited around nanoribbons 1002 using any suitable deposition process, such as atomic layer deposition (ALD). The gate dielectric may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric is hafnium oxide with a thickness between about 1 nm and about 5 nm. In some embodiments, the gate dielectric includes one or more silicates (e.g., titanium silicate, tungsten silicate, niobium silicate, and silicates of other transition metals). The gate dielectric may be a multilayer structure, in some examples. For instance, the gate dielectric may include a first layer on nanoribbons 1002, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on the gate dielectric to improve its quality when a high-k dielectric material is used. In some embodiments, the high-k material can be nitridized to improve its aging resistance.

The gate electrode may be deposited over the gate dielectric and can be any conductive structure. In some embodiments, the gate electrode includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

According to some embodiments, a gate cap 1104 may be formed by first recessing the gate electrode and filling the recess with a dielectric material. The dielectric material may then be polished such that its top surface is substantially coplanar with any adjacent spacer structures or material within the source/drain trench. Gate cap 1104 may be any suitable dielectric material, such as silicon nitride.

FIGS. 12A and 12B depict cross-section views of the structure shown in FIGS. 11A and 11B, respectively, following the removal of semiconductor materials from the backside and replacement with dielectric materials, according to some embodiments. Once all front-side processes have been performed across the integrated circuit, substrate 201 may be removed via any arrangement of grinding, polishing, and/or chemical etching processes. According to some embodiments, all materials are removed from the backside up until at least a bottom surface of dielectric fill 306 is exposed, which may also expose a bottom surface of the adjacent subfins regions 304. According to some embodiments, subfin regions 304 are also removed from the backside and replaced with dielectric material 1202, which may include any number of dielectric layers. In some examples, dielectric material 1202 also encompasses dielectric fill 306 and may the same or similar dielectric material as dielectric fill 306. In some examples, dielectric fill 306 is also removed from the backside and dielectric material 1202 represents freshly deposited dielectric material on the backside of the integrated circuit. In any case, the dielectric regions made up of bottom dielectric layer 704 and dielectric fill 802 extend into dielectric material 1202, according to some embodiments.

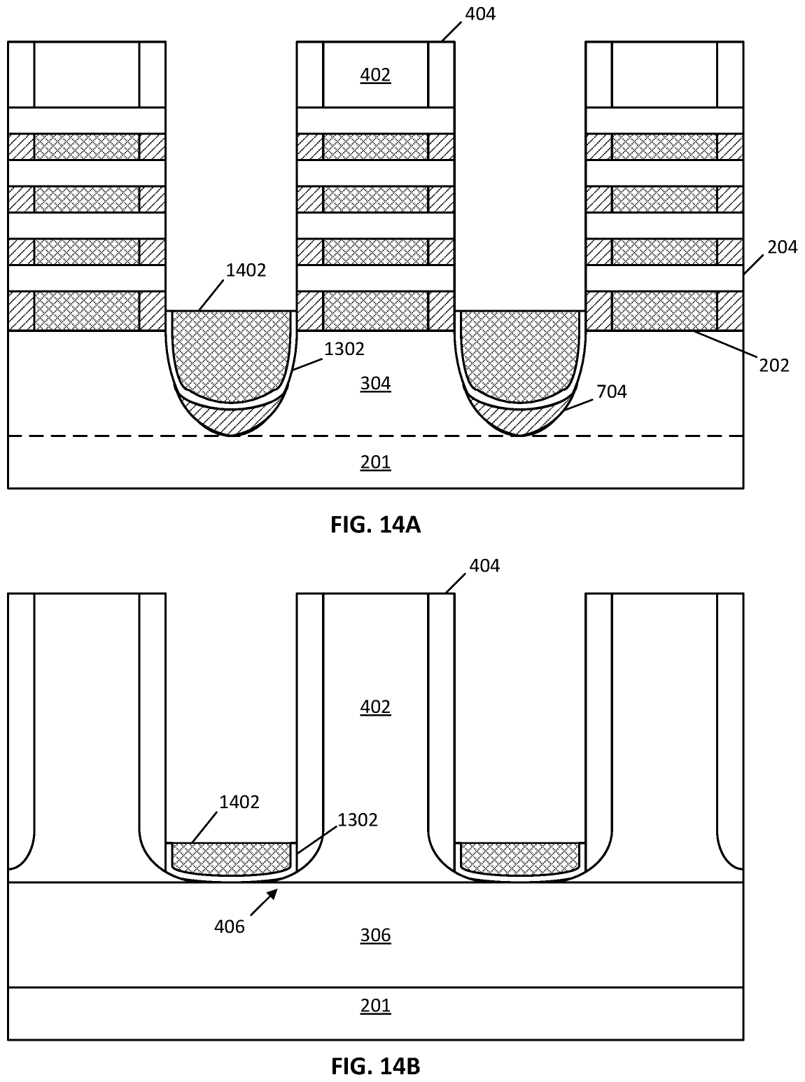

FIGS. 13A and 13B depict cross-section views of the structure shown in FIGS. 7A and 7B, respectively, following the formation of a dielectric liner 1302 along all exposed surfaces within the source/drain trenches, according to some embodiments. Dielectric liner 1302 may have a thickness between about 3 nm and about 7 nm and may be any suitable dielectric material that exhibits a high etch selectivity to the material of spacer structures 404 and internal spacers 702. In one example, dielectric liner 1302 includes aluminum oxide. Dielectric liner 1302 may also form on the top surface of bottom dielectric layer 704 within the subfin recesses. As seen in FIG. 14B, dielectric liner 1302 covers gate foot regions 406.

FIGS. 14A and 14B depict cross-section views of the structure shown in FIGS. 13A and 13B, respectively, following the formation of a sacrificial material 1402 within the source/drain trenches and subsequent trimming of dielectric liner 1302, according to some embodiments. In some example, sacrificial material 1402 includes carbon hard mask (CHM) that can be deposited and recessed to a final height within the source/drain trenches. According to some embodiments, a top surface of sacrificial material 1402 above the subfin recesses is at least above a top surface of the adjacent subfin regions 304. According to some embodiments, the top surface of sacrificial material 1402 is below the bottom surface of the bottom-most semiconductor layer 204 in the fins. Sacrificial material 1402 also remains along the bottom of other portions of the source/drain trench as illustrated in FIG. 14B.

According to some embodiments, all portions of dielectric liner 1302 not protected by sacrificial material 1402 are removed. In some examples, dielectric liner 1302 may be removed using an isotropic ammonia-based etch. Dielectric liner 1302 remains at least on all surfaces of subfin regions 304 within the subfin recesses, according to some embodiments.

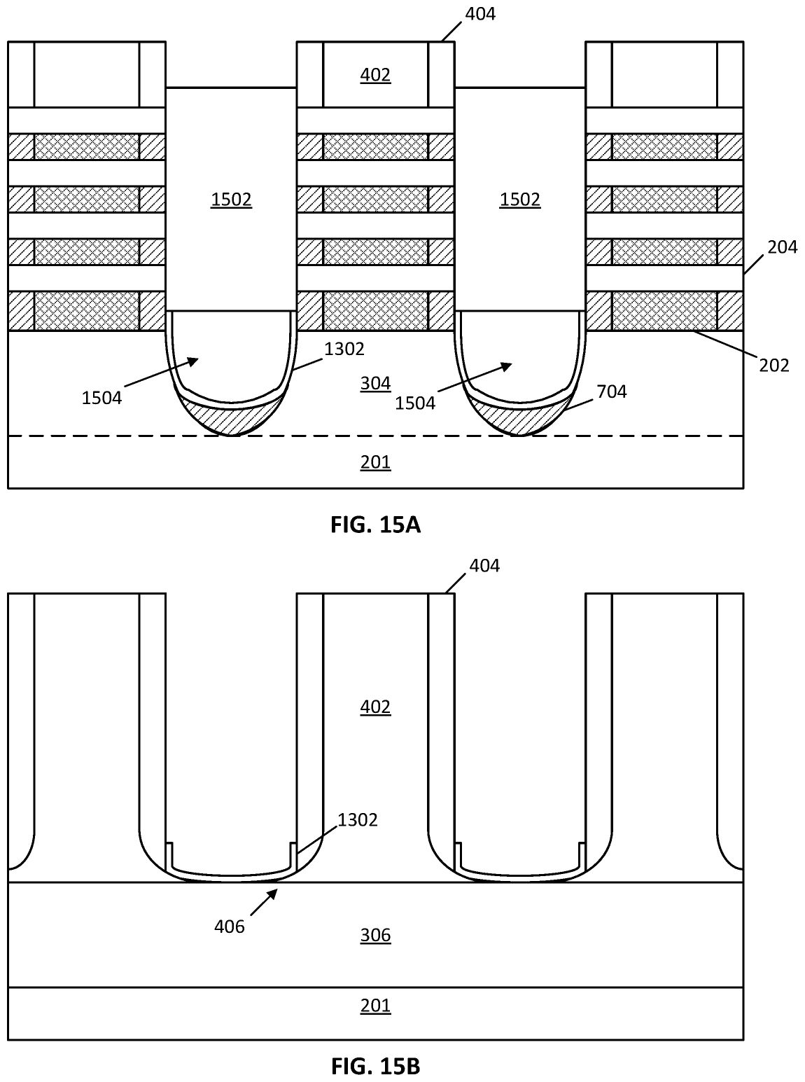

FIGS. 15A and 15B depict cross-section views of the structure shown in FIGS. 14A and 14B, respectively, following the removal of sacrificial material 1402 and formation of source or drain regions 1502 within the source/drain trenches, according to some embodiments. Sacrificial material 1402 may be removed using an ashing process or any other suitable isotropic etching process. Source or drain regions 1502 may be formed in the areas that had been previously occupied by the exposed fins between spacer structures 404. According to some embodiments, source or drain regions 1502 are epitaxially grown from the exposed semiconductor material at the ends of semiconductor layers 204. In some example embodiments, source or drain regions 1502 are n-channel source or drain regions (e.g., epitaxial silicon with n-type dopants) or p-channel source or drain regions (e.g., epitaxial SiGe with p-type dopants). Due to the presence of dielectric liner 1302, no part of source or drain regions 1502 are grown from subfin regions 304, according to some embodiments. In some examples, cavities 1504 are formed beneath source or drain regions 1502 in the areas that had previously been the subfin recesses. Cavities 1504 may be closed off at the top (due to the growth of source or drain regions 1502) or may have openings on either side of the top along the second direction.

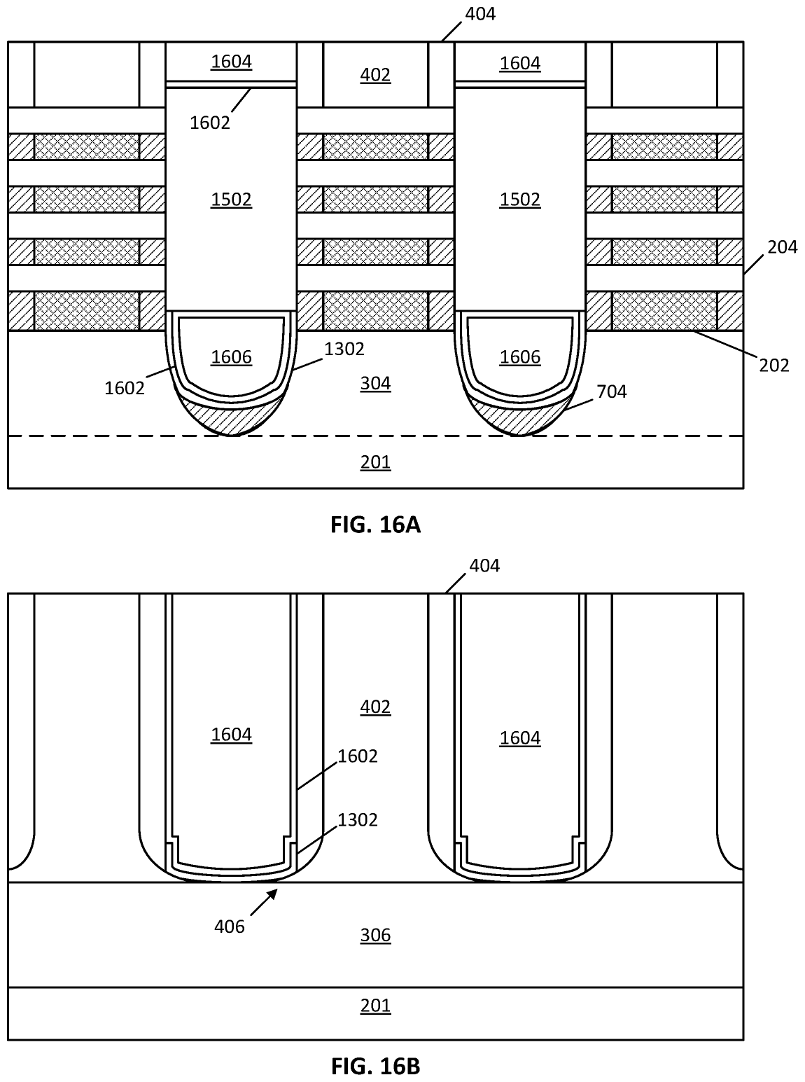

FIGS. 16A and 16B depict cross-section views of the structure shown in FIGS. 15A and 15B, respectively, following the formation of additional dielectric materials within the source/drain trench, according to some embodiments. One or more other dielectric materials are formed within the source/drain trench to protect source or drain regions 1502 from certain process operations and to fill any dead space between source or drain regions 1502 within the source/drain trenches. Accordingly, one or more dielectric layers 1602 may be deposited on surfaces of source or drain regions 1502 and also on surfaces within cavities 1504. In some examples, one or more dielectric layers 1602 include at least a layer of silicon nitride. A dielectric fill 1604 is provided between adjacent source or drain regions 1502 along a given source/drain trench running in the second direction. In some examples, dielectric fill 1604 occupies a remaining volume within the source/drain trench around and over portions of source or drain regions 1502. Dielectric fill 1604 may be any suitable dielectric material, such as silicon dioxide. In some examples, dielectric fill 1604 extends up to and planar with a top surface of spacer structures 404 (e.g., following a polishing procedure). Dielectric fill 1604 may be provided on one or more dielectric layers 1602 within the source/drain trenches.

According to some embodiments, the formation of one or more dielectric layers 1602 and/or dielectric fill 1604 closes any gaps or openings at the top of cavities 1504, leaving behind airgaps 1606 within a central portion of cavities 1504. Airgaps 1606 may be filled with an inert gas (such as argon) or may have substantially no appreciable gas at a vacuum pressure.

FIGS. 17A and 17B depict cross-section views of the structure shown in FIGS. 16A and 16B, respectively, following the completion of additional transistor structures such as source/drain contacts 1702, gate structures 1704, gate caps 1706, and a backside dielectric material 1708. These structures are all formed in the same fashion as discussed above with reference to FIGS. 9A-12A and 9B-12B. The dielectric regions that include at least bottom dielectric layer 704 and dielectric liner 1302 extend into dielectric material 1708, according to some embodiments.

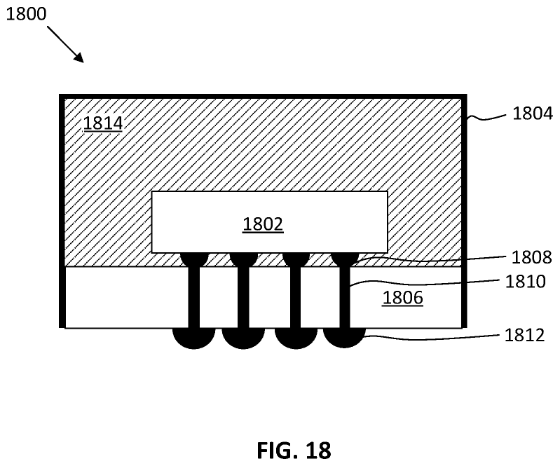

FIG. 18 illustrates an example embodiment of a chip package 1800, in accordance with an embodiment of the present disclosure. As can be seen, chip package 1800 includes one or more dies 1802. One or more dies 1802 may include at least one integrated circuit having semiconductor devices, such as any of the semiconductor devices disclosed herein. One or more dies 1802 may include any other circuitry used to interface with other devices formed on the dies, or other devices connected to chip package 1800, in some example configurations.

As can be further seen, chip package 1800 includes a housing 1804 that is bonded to a package substrate 1806. The housing 1804 may be any standard or proprietary housing, and may provide, for example, electromagnetic shielding and environmental protection for the components of chip package 1800. The one or more dies 1802 may be conductively coupled to a package substrate 1806 using connections 1808, which may be implemented with any number of standard or proprietary connection mechanisms, such as solder bumps, ball grid array (BGA), pins, or wire bonds, to name a few examples. Package substrate 1806 may be any standard or proprietary package substrate, but in some cases includes a dielectric material having conductive pathways (e.g., including conductive vias and lines) extending through the dielectric material between the faces of package substrate 1806, or between different locations on each face. In some embodiments, package substrate 1806 may have a thickness less than 1 millimeter (e.g., between 0.1 millimeters and 0.5 millimeters), although any number of package geometries can be used. Additional conductive contacts 1812 may be disposed at an opposite face of package substrate 1806 for conductively contacting, for instance, a printed circuit board (PCB). One or more vias 1810 extend through a thickness of package substrate 1806 to provide conductive pathways between one or more of connections 1808 to one or more of contacts 1812. Vias 1810 are illustrated as single straight columns through package substrate 1806 for ease of illustration, although other configurations can be used (e.g., damascene, dual damascene, through-silicon via, or an interconnect structure that meanders through the thickness of substrate 1806 to contact one or more intermediate locations therein). In still other embodiments, vias 1810 are fabricated by multiple smaller stacked vias, or are staggered at different locations across package substrate 1806. In the illustrated embodiment, contacts 1812 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1812, to inhibit shorting.

In some embodiments, a mold material 1814 may be disposed around the one or more dies 1802 included within housing 1804 (e.g., between dies 1802 and package substrate 1806 as an underfill material, as well as between dies 1802 and housing 1804 as an overfill material). Although the dimensions and qualities of the mold material 1814 can vary from one embodiment to the next, in some embodiments, a thickness of mold material 1814 is less than 1 millimeter. Example materials that may be used for mold material 1814 include epoxy mold materials, as suitable. In some cases, the mold material 1814 is thermally conductive, in addition to being electrically insulating.

### Methodology

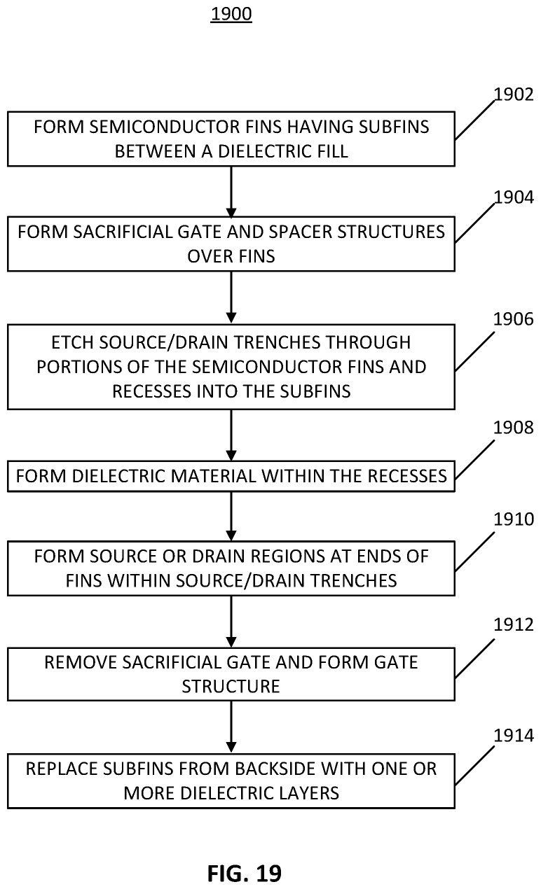

FIG. 19 is a flow chart of a method 1900 for forming at least a portion of an integrated circuit, according to an embodiment. Various operations of method 1900 may be illustrated in FIGS. 2A-17A and 2B-17B. However, the correlation of the various operations of method 1900 to the specific components illustrated in the aforementioned figures is not intended to imply any structural and/or use limitations. Rather, the aforementioned figures provide example embodiments of method 1900. Other operations may be performed before, during, or after any of the operations of method 1900. For example, method 1900 does not explicitly describe various standard processes that are usually performed to form transistor structures. Some of the operations of method 1900 may be performed in a different order than the illustrated order.

Method 1900 begins with operation 1902 where a plurality of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of SiGe can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches, according to some examples. The fins may also include a cap structure over each fin that is used to define the locations of the fins during, for example, an RIE process. The cap structure may be a dielectric material, such as silicon nitride.

According to some embodiments, a dielectric fill is formed around subfins of the one or more fins. In some embodiments, the dielectric fill extends between each pair of adjacent parallel fins and runs lengthwise in the same direction as the fins. In some embodiments, the anisotropic etching process that forms the fins also etches into a portion of the substrate and the dielectric fill may be formed within the recessed portions of the substrate. Accordingly, the dielectric fill acts as shallow trench isolation (STI) between adjacent fins. The dielectric fill may be any suitable dielectric material, such as silicon dioxide. Lower portions of the fins adjacent to the dielectric fill may be identified as the subfins.

Method 1900 continues with operation 1904 where sacrificial gates are formed over the fins. The sacrificial gates may be patterned using gate masking layers in strips that run orthogonally over the fins and parallel to one another (e.g., forming a cross-hatch pattern). The gate masking layers may be any suitable hard mask material, such as CHM or silicon nitride. The sacrificial gates themselves may be formed from any suitable material that can be selectively removed at a later time without damaging the semiconductor material of the fins. In one example, the sacrificial gates include polysilicon.

According to some embodiments, spacer structures are also formed on sidewalls of at least the sacrificial gates. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may be any suitable dielectric material, such as silicon nitride or silicon oxynitride.

Method 1900 continues with operation 1906 where exposed portions of the fins are removed to form source/drain trenches. Any exposed portions of the fins not covered by the sacrificial gates or spacer structures may be removed using any anisotropic etching process, such as reactive ion etching (RIE). According to some embodiments, the etching process continues past the fins and removes portions of the subfins between the dielectric fill. The removed subfin portions create subfin recesses that extend below a top surface of the adjacent dielectric fill within the source/drain trenches. According to some embodiments, sacrificial layers of the fins may be recessed (e.g., via isotropic etch process) followed by deposition of internal spacers (e.g., silicon nitride), as described above.

Method 1900 continues with operation 1908 where dielectric material is formed within the subfin recesses. According to some embodiments, dielectric material deposited during the formation of the internal spacers as discussed above is also deposited at the bottom of the subfin recesses and remains after forming the internal spacers. Thus, the bottom dielectric layer may have the same dielectric material as the internal spacers.

In one example, a dielectric fill is formed within a remaining volume of the subfin recesses on the bottom dielectric layer. The dielectric fill may be formed within the source/drain trenches and subsequently recessed to a final height that puts a top surface of the dielectric fill at least above a top surface of the adjacent subfin or a top surface of the adjacent STI. According to some embodiments, the top surface of the dielectric fill is below the bottom surface of the bottom-most semiconductor layer in the fins. The dielectric fill may be any suitable dielectric material that exhibits good etch selectively with the spacer structures and the internal spacers. In some examples, the dielectric fill includes silicon dioxide and the spacer structures and internal spacers include silicon nitride.

In another example, a dielectric liner is formed along surfaces of the source/drain trench and on the bottom dielectric layer within the subfin recesses. Accordingly, the dielectric liner may be formed at least on all exposed semiconductor surfaces within the subfin recesses. The dielectric liner may have a thickness between about 3 nm and about 7 nm and may be any suitable dielectric material that exhibits a high etch selectivity to the material of the spacer structures and the internal spacers. In one example, the dielectric liner includes aluminum oxide.

According to some embodiments, a sacrificial material is formed on a lower portion of the source/drain trench to protect a lower portion of the dielectric liner while the exposed top portion of the dielectric liner is removed. The dielectric liner may be removed using any suitable isotropic etching process, such as an ammonia-based etching process. After removal of the sacrificial material, the dielectric liner remains along lower surfaces of the source/drain trench and at least along all surfaces within the subfin recesses.

Method 1900 continues with operation 1910 where source or drain regions are formed at opposite ends of the fins within the source/drain trenches. The source or drain regions may be formed in the areas that had been previously occupied by the exposed fins between the spacer structures. According to some embodiments, the source or drain regions are epitaxially grown from the exposed semiconductor material of the fins (or nanoribbons, nanowires or nanosheets, as the case may be) along the exterior walls of the spacer structures. In some example embodiments, the source or drain regions are NMOS source or drain regions (e.g., epitaxial silicon with n-type dopants) or PMOS source or drain regions (e.g., epitaxial SiGe with p-type dopants). A dielectric fill may be formed between and over the source or drain regions along a given source/drain trench. The dielectric fill may be any suitable dielectric material, such as silicon dioxide. In some examples, the dielectric fill extends over the source or drain regions up to and planar with a top surface of the spacer structures. The dielectric fill also acts as an electrical insulator between adjacent source or drain regions, although some adjacent source or drain regions may have merged together during their growth. According to some embodiments, no part of the source or drain regions are grown from the subfins due to the presence of either the dielectric fill within the subfin recesses or the dielectric liner within the subfin recesses.

Method 1900 continues with operation 1912 where the sacrificial gate is replaced with a gate structure. According to some embodiments, the sacrificial gate may be removed along with any sacrificial layers within the exposed fins between the spacer structures (in the case of GAA structures). A gate structure may then be formed in place of the sacrificial gate. The gate structure may include both a gate dielectric and a gate electrode. The gate dielectric is first formed over the exposed semiconductor regions between the spacer structures followed by forming the gate electrode within the remainder of the gate trench between the spacer structures, according to some embodiments. The gate dielectric may include any number of dielectric layers deposited using a CVD process, such as ALD. The gate electrode can include any conductive material, such as a metal, metal alloy, or polysilicon. The gate electrode may be deposited using electroplating, electroless plating, CVD, ALD, PECVD, or PVD, to name a few examples.

According to some embodiments, contacts are also formed over the source or drain regions. The contacts may include any suitable conductive material, such as tungsten, molybdenum, ruthenium, or cobalt. The dielectric fill over the source or drain regions may be recessed to expose the source or drain regions prior to forming the contacts within the recessed area. The contacts may include any number of different conductive materials and may extend over the top surfaces of any number of source or drain regions within the source/drain trench.

Method 1900 continues with operation 1914 where the substrate and subfins are replaced from the backside by one or more dielectric layers. Once all front-side processes have been performed across the integrated circuit, the substrate may be removed via any arrangement of grinding, polishing, and/or chemical etching processes. According to some embodiments, all materials are removed from the backside up until at least a bottom surface of the dielectric fill between the subfins is exposed. According to some embodiments, the exposed subfins are also removed from the backside and replaced with dielectric material, which may include any number of dielectric layers. Ultimately, various dielectric materials are formed on the backside of the integrated circuit around the dielectric regions that were formed within the subfin recesses.

### Example System

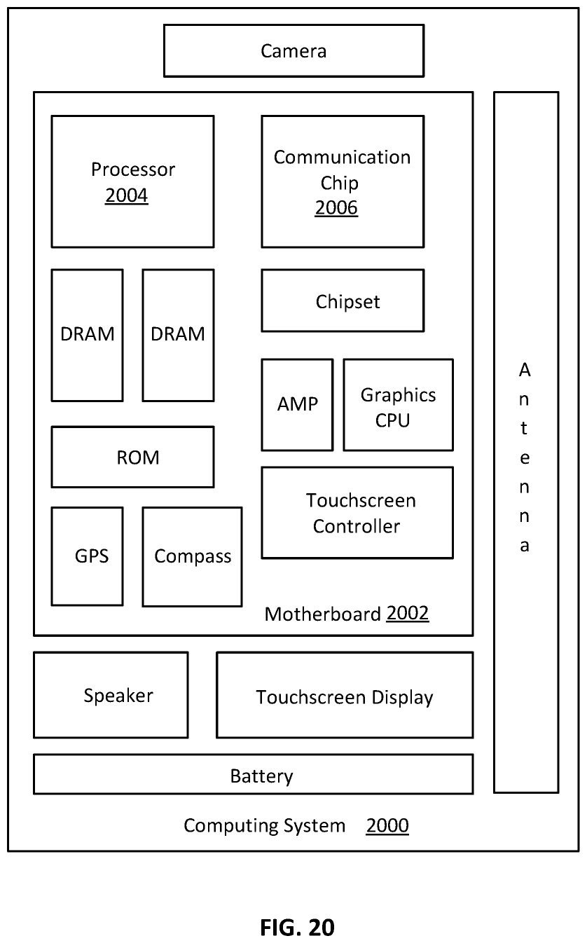

FIG. 20 is an example computing system implemented with one or more of the integrated circuit structures as disclosed herein, in accordance with some embodiments of the present disclosure. As can be seen, the computing system 2000 houses a motherboard 2002. The motherboard 2002 may include a number of components, including, but not limited to, a processor 2004 and at least one communication chip 2006, each of which can be physically and electrically coupled to the motherboard 2002, or otherwise integrated therein. As will be appreciated, the motherboard 2002 may be, for example, any printed circuit board (PCB), whether a main board, a daughterboard mounted on a main board, or the only board of system 2000, etc.

Depending on its applications, computing system 2000 may include one or more other components that may or may not be physically and electrically coupled to the motherboard 2002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 2000 may include one or more integrated circuit structures or devices configured in accordance with an example embodiment (e.g., a module including an integrated circuit device on a substrate, the substrate having one or more semiconductor devices that include dielectric material in cavities beneath the source or drain regions, as variously provided herein). In some embodiments, multiple functions can be integrated into one or more chips (e.g., for instance, note that the communication chip 2006 can be part of or otherwise integrated into the processor 2004).

The communication chip 2006 enables wireless communications for the transfer of data to and from the computing system 2000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 2000 may include a plurality of communication chips 2006. For instance, a first communication chip 2006 may be dedicated to shorter range wireless communications such as Wi-Fi and Bluetooth and a second communication chip 2006 may be dedicated to longer range wireless communications such as GPS, EDGE, GPRS, CDMA, WiMAX, LTE, Ev-DO, and others.

The processor 2004 of the computing system 2000 includes an integrated circuit die packaged within the processor 2004. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 2006 also may include an integrated circuit die packaged within the communication chip 2006. In accordance with some such example embodiments, the integrated circuit die of the communication chip includes one or more semiconductor devices as variously described herein. As will be appreciated in light of this disclosure, note that multi-standard wireless capability may be integrated directly into the processor 2004 (e.g., where functionality of any chips 2006 is integrated into processor 2004, rather than having separate communication chips). Further note that processor 2004 may be a chip set having such wireless capability. In short, any number of processor 2004 and/or communication chips 2006 can be used. Likewise, any one chip or chip set can have multiple functions integrated therein.

In various implementations, the computing system 2000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 2000 may be combined or integrated in a system-on-a-chip (SoC) architecture. In some embodiments, the components may be hardware components, firmware components, software components or any suitable combination of hardware, firmware or software.

### FURTHER EXAMPLE EMBODIMENTS

The following examples pertain to further embodiments, from which numerous permutations and configurations will be apparent.

Example 1 is an integrated circuit that includes a semiconductor device having one or more semiconductor bodies extending in a first direction from a source or drain region and a gate structure extending over the one or more semiconductor bodies in a second direction different from the first direction, a dielectric layer beneath the gate structure, and a dielectric fill beneath the source or drain region. A top surface of the dielectric fill is above a top surface of the dielectric layer.

Example 2 includes the integrated circuit of Example 1, wherein the one or more semiconductor bodies are nanoribbons, nanosheets, or nanowires that comprise germanium, silicon, or any combination thereof.

Example 3 includes the integrated circuit of Example 2, wherein the top surface of the dielectric fill is below a bottom surface of a bottommost nanoribbon, nanosheet, or nanowire.

Example 4 includes the integrated circuit of any one of Examples 1-3, wherein the dielectric layer is a first dielectric layer, and the integrated circuit further comprises a second dielectric layer beneath the dielectric fill, such that the second dielectric layer is between the dielectric fill and the first dielectric layer.

Example 5 includes the integrated circuit of Example 4, wherein the dielectric fill comprises silicon and oxygen and the second dielectric layer comprises silicon and nitrogen.

Example 6 includes the integrated circuit of any one of Examples 1-5, further comprising a silicide layer comprising silicon and titanium on a top surface of the source or drain region.

Example 7 includes the integrated circuit of any one of Examples 1-6, wherein the dielectric fill extends in a third direction through at least a portion of a total thickness of the dielectric layer.

Example 8 includes the integrated circuit of any one of Examples 1-7, wherein the dielectric fill contacts a lower portion of the gate structure.

Example 9 includes the integrated circuit of any one of Examples 1-8, wherein the first direction is orthogonal to the second direction.

Example 10 includes the integrated circuit of any one of Examples 1-9, wherein the gate structure comprises a gate dielectric and a gate electrode on the gate dielectric.

Example 11 includes the integrated circuit of any one of Examples 1-10, wherein the top surface of the dielectric fill contacts a bottom surface of the source or drain region.

Example 12 is a printed circuit board comprising the integrated circuit of any one of Examples 1-11,

Example 13 is an electronic device that includes a chip package comprising one or more dies. At least one of the one or more dies includes a semiconductor device having one or more semiconductor bodies extending in a first direction from a source or drain region and a gate structure extending over the one or more semiconductor bodies in a second direction different from the first direction, a dielectric layer beneath the gate structure, and a dielectric fill beneath the source or drain region. A top surface of the dielectric fill contacts a bottom surface of the source or drain region and the top surface of the dielectric fill is above a top surface of the dielectric layer.

Example 14 includes the electronic device of Example 13, wherein the one or more semiconductor bodies are nanoribbons, nanosheets, or nanowires that comprise germanium, silicon, or any combination thereof.

Example 15 includes the electronic device of Example 14, wherein the top surface of the dielectric fill is below a bottom surface of a bottommost nanoribbon, nanosheet, or nanowire.

Example 16 includes the electronic device of any one of Examples 13-15, wherein the dielectric layer is a first dielectric layer, and the at least one of the one or more dies further comprises a second dielectric layer beneath the dielectric fill, such that the second dielectric layer is between the dielectric fill and the first dielectric layer.

Example 17 includes the electronic device of Example 16, wherein the dielectric fill comprises silicon and oxygen and the second dielectric layer comprises silicon and nitrogen.

Example 18 includes the electronic device of any one of Examples 13-17, further comprising a silicide layer comprising silicon and titanium on a top surface of the source or drain region.

Example 19 includes the electronic device of any one of Examples 13-18, wherein the dielectric fill extends in a third direction through at least a portion of a total thickness of the dielectric layer.

Example 20 includes the electronic device of any one of Examples 13-19, wherein the dielectric fill contacts a lower portion of the gate structure.

Example 21 includes the electronic device of any one of Examples 13-20, wherein the first direction is orthogonal to the second direction.

Example 22 includes the electronic device of any one of Examples 13-21, wherein the gate structure comprises a gate dielectric and a gate electrode on the gate dielectric, wherein the gate dielectric is on the dielectric layer.

Example 23 includes the electronic device of any one of Examples 13-22, further comprising a printed circuit board, wherein the chip package is attached to the printed circuit board.

Example 24 is a method of forming an integrated circuit. The method includes forming a multilayer fin extending in a first direction over a substrate having first material layers alternating with second material layers, and a subfin beneath the alternating material layers; forming a first dielectric layer adjacent to the subfin; forming a sacrificial gate and spacers on sidewalls of the sacrificial gate, the sacrificial gate extending in a second direction over the multilayer fin, the second direction being different from the first direction; removing an exposed portion of the multilayer fin adjacent to the sacrificial gate and at least a portion of the subfin below the exposed portion of the multilayer fin such that a recess is formed in the subfin; forming a dielectric material within the recess, such that a top surface of the dielectric material is above a top surface of the subfin; forming a source or drain region over the dielectric material and coupled to ends of the second material layers; removing the sacrificial gate and forming a gate structure over the first material layers; removing the subfin from a backside of the integrated circuit; and forming a second dielectric layer in place of the subfin.

Example 25 includes the method of Example 24, wherein the first material layers comprise silicon and germanium and the second material layers comprise silicon.

Example 26 includes the method of Example 24 or 25, wherein forming the dielectric material comprises filling the recess with the dielectric material.

Example 27 includes the method of any one of Examples 24-26, wherein forming the dielectric material comprises forming a dielectric liner along sidewalls of the recess.

Example 28 includes the method of Example 27, wherein forming the source or drain region comprises epitaxially growing the source or drain region above the dielectric liner such that an airgap exists between the source or drain region and the dielectric liner within the recess.

Example 29 includes the method of Example 28, wherein the dielectric liner is a first dielectric liner and the method further comprises forming a second dielectric liner within the recess, the second dielectric liner forming on the first dielectric liner and on a lower surface of the source or drain region.

Example 30 is an integrated circuit that includes one or more semiconductor bodies extending in a first direction from a source or drain region, a gate structure extending over the one or more semiconductor bodies in a second direction different from the first direction, a dielectric layer beneath the gate structure, and a dielectric liner beneath the source or drain region. The dielectric liner is within a cavity in the dielectric layer such that an air gap exists between a bottom surface of the source or drain region and the dielectric liner within the cavity.

Example 31 includes the integrated circuit of Example 30, wherein the one or more semiconductor bodies are nanoribbons, nanosheets, or nanowires that comprise germanium, silicon, or any combination thereof.

Example 32 includes the integrated circuit of Example 31, wherein an entirety of the dielectric liner is below a bottom surface of a bottommost nanoribbon, nanosheet, or nanowire.

Example 33 includes the integrated circuit of any one of Examples 30-32, wherein the dielectric layer is a first dielectric layer, and the integrated circuit further comprises a second dielectric layer beneath the dielectric liner, such that the second dielectric layer is between the dielectric liner and the first dielectric layer.

Example 34 includes the integrated circuit of any one of Examples 30-33, wherein the dielectric liner comprises aluminum and oxygen and the dielectric layer comprises silicon and oxygen.

Example 35 includes the integrated circuit of any one of Examples 30-34, wherein the dielectric liner extends to a height at least above a top surface of the dielectric layer.

Example 36 includes the integrated circuit of any one of Examples 30-35, wherein the dielectric liner is a first dielectric liner, and the integrated circuit further comprises a second dielectric liner on the first dielectric liner and on a bottom surface of the source or drain region within the cavity.

Example 37 includes the integrated circuit of Example 36, wherein the second dielectric liner comprises silicon and nitrogen.

Example 38 includes the integrated circuit of any one of Examples 30-37, wherein the first direction is orthogonal to the second direction.

Example 39 includes the integrated circuit of any one of Examples 30-38, wherein the gate structure comprises a gate dielectric and a gate electrode on the gate dielectric, wherein the gate dielectric is on the dielectric layer.

Example 40 is a printed circuit board that includes the integrated circuit of any one of Examples 30-39.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor device having one or more semiconductor bodies extending in a first direction from a source or drain region, and a gate structure extending over the one or more semiconductor bodies in a second direction different from the first direction;
a dielectric layer beneath the gate structure; and
a dielectric fill beneath the source or drain region, such that a top surface of the dielectric fill is above a top surface of the dielectric layer.

2. The integrated circuit of claim 1, wherein the one or more semiconductor bodies are nanoribbons, nanosheets, or nanowires that comprise germanium, silicon, or any combination thereof.

3. The integrated circuit of claim 2, wherein the top surface of the dielectric fill is below a bottom surface of a bottommost nanoribbon, nanosheet, or nanowire.

4. The integrated circuit of claim 1, wherein the dielectric fill extends in a third direction through at least a portion of a total thickness of the dielectric layer.

5. The integrated circuit of claim 1, wherein the dielectric fill contacts a lower portion of the gate structure.

6. The integrated circuit of claim 1, wherein the first direction is orthogonal to the second direction.

7. The integrated circuit of claim 1, wherein the top surface of the dielectric fill contacts a bottom surface of the source or drain region.

8. A printed circuit board comprising the integrated circuit of claim 1.

9. An electronic device, comprising:
a chip package comprising one or more dies, at least one of the one or more dies comprising
a semiconductor device having one or more semiconductor bodies extending in a first direction from a source or drain region, and a gate structure extending over the one or more semiconductor bodies in a second direction different from the first direction;
a dielectric layer beneath the gate structure; and
a dielectric fill beneath the source or drain region, such that a top surface of the dielectric fill contacts a bottom surface of the source or drain region and the top surface of the dielectric fill is above a top surface of the dielectric layer.

10. The electronic device of claim 9, wherein the one or more semiconductor bodies are nanoribbons, nanosheets, or nanowires that comprise germanium, silicon, or any combination thereof.

11. The electronic device of claim 10, wherein the top surface of the dielectric fill is below a bottom surface of a bottommost nanoribbon, nanosheet, or nanowire.

12. The electronic device of claim 9, wherein the dielectric layer is a first dielectric layer, and the at least one of the one or more dies further comprises a second dielectric layer beneath the dielectric fill, such that the second dielectric layer is between the dielectric fill and the first dielectric layer.

13. The electronic device of claim 12, wherein the dielectric fill comprises silicon and oxygen and the second dielectric layer comprises silicon and nitrogen.

14. The electronic device of claim 9, wherein the dielectric fill contacts a lower portion of the gate structure.

15. An integrated circuit comprising:
one or more semiconductor bodies extending in a first direction from a source or drain region;
a gate structure extending over the one or more semiconductor bodies in a second direction different from the first direction;
a dielectric layer beneath the gate structure; and
a dielectric liner beneath the source or drain region, the dielectric liner being within a cavity in the dielectric layer such that an air gap exists between a bottom surface of the source or drain region and the dielectric liner within the cavity.

16. The integrated circuit of claim 15, wherein the one or more semiconductor bodies are nanoribbons, nanosheets, or nanowires that comprise germanium, silicon, or any combination thereof.

17. The integrated circuit of claim 16, wherein an entirety of the dielectric liner is below a bottom surface of a bottommost nanoribbon, nanosheet, or nanowire.

18. The integrated circuit of claim 15, wherein the dielectric layer is a first dielectric layer, and the integrated circuit further comprises a second dielectric layer beneath the dielectric liner, such that the second dielectric layer is between the dielectric liner and the first dielectric layer.

19. The integrated circuit of claim 15, wherein the dielectric liner extends to a height at least above a top surface of the dielectric layer.

20. The integrated circuit of claim 15, wherein the dielectric liner is a first dielectric liner, and the integrated circuit further comprises a second dielectric liner on the first dielectric liner and on a bottom surface of the source or drain region within the cavity.
